(19) United States
(12) Patent Application Publication
(10) Pub. No.: US 2026/0321551 A1
(43) Pub. Date: Oct. 15, 2026

(54) PLASMA PROCESSING APPARATUS

(71) Applicant: Tokyo Electron Limited, Tokyo (JP)

(72) Inventors: Nozomu NAGASHIMA, Miyagi (JP); Koichi NAGAMI, Miyagi (JP); Daisuke YOSHIKOSHI, Miyagi (JP); Kunihiko YAMAGATA, Miyagi (JP); Tomotaka SUKIGARA, Miyagi (JP)

(73) Assignee: Tokyo Electron Limited, Tokyo (JP)

(21) Appl. No.: 19/694,116

(22) Filed: Jun. 1, 2026

Related U.S. Application Data
(63) Continuation of application No. PCT/JP2023/044920, filed on Dec. 14, 2023.

(51) Int. Cl. H01J 37/32

(52) U.S. Cl. CPC H01J 37/32568; H01J 37/32091; H01J 37/32174; H01J 2237/334

(57) ABSTRACT

A plasma processing apparatus includes a chamber, a substrate support, a radio frequency power supply, a load, a transmitting coil, a receiving coil, a rectifying and smoothing circuit, an energy storage, and a ground frame. The radio frequency power supply is configured to generate radio frequency power. The load is in the chamber and is connected to the energy storage. The receiving coil is configured to receive power from the transmitting coil by electromagnetic induction coupling and is connected to the energy storage via the rectifying and smoothing circuit. The ground frame is configured to couple to ground and surrounds the substrate support together with the chamber. The transmitting coil is outside the ground frame, and the receiving coil is, together with the rectifying and smoothing circuit and the energy storage, in a space outside the chamber and inside the ground frame.

### CROSS-REFERENCE TO RELATED APPLICATIONS

This application is a continuation application of PCT Application No. PCT/JP2023/044920, filed on Dec. 14, 2023. The entire contents of the above listed PCT and priority applications are incorporated herein by reference.

### BACKGROUND

### Field

Example embodiments of the present disclosure relate to a plasma processing apparatus.

### Description of the Related Art

A plasma processing apparatus is used in plasma processing. The plasma processing apparatus includes a chamber and a substrate support (stage) disposed in the chamber. The substrate support has a base (lower electrode) and an electrostatic chuck that holds a substrate. Inside the electrostatic chuck, a temperature adjusting element (for example, a heater) for adjusting the temperature of the substrate is located. In addition, between the temperature adjusting element and a power supply for the temperature adjusting element, a filter is provided that attenuates or blocks radio frequency noise entering on lines such as power supply lines and/or signal lines from radio frequency electrodes and/or other electrical members in the chamber. One type of such a plasma processing apparatus is described in Japanese Unexamined Patent Publication No. 2015-173027.

### SUMMARY

In one example embodiment, a plasma processing apparatus is provided. The plasma processing apparatus includes a plasma processing chamber, a substrate support, a radio frequency power supply, an electrode or an antenna, a load, a transmitting coil, a receiving coil, a rectifying and smoothing circuit, an energy storage, and a ground frame. The substrate support is in the plasma processing chamber. The radio frequency power supply is configured to generate radio frequency power. The electrode or the antenna is electrically connected to the radio frequency power supply and configured to receive the radio frequency power to generate plasma from a gas in the plasma processing chamber. The load is located in the plasma processing chamber or in the substrate support. The receiving coil is configured to receive power from the transmitting coil by electromagnetic induction coupling. The rectifying and smoothing circuit is configured to convert power from the receiving coil into DC power. The energy storage is electrically connected between the rectifying and smoothing circuit and the load. The ground frame is configured to couple to ground and surrounds the substrate support together with the plasma processing chamber. The ground frame defines a space outside the plasma processing chamber to accommodate the rectifying and smoothing circuit and the energy storage in the space. The transmitting coil is outside the ground frame. The receiving coil is in the space of the ground frame.

### BRIEF DESCRIPTION OF THE DRAWINGS

FIG. 1 is a diagram for explaining a configuration example of a plasma processing system.

FIG. 2 is a diagram for explaining a configuration example of a capacitively coupled plasma processing apparatus.

FIG. 3 is a diagram schematically illustrating a plasma processing apparatus according to one example embodiment.

FIG. 4 is a diagram schematically illustrating a plasma processing apparatus according to another example embodiment.

FIG. 5 is a diagram schematically illustrating a plasma processing apparatus according to yet another example embodiment.

FIG. 6 is a diagram schematically illustrating a plasma processing apparatus according to yet another example embodiment.

FIG. 7 is a diagram schematically illustrating a plasma processing apparatus according to yet another example embodiment.

FIG. 8 is a diagram illustrating a power transmitter according to one example embodiment.

FIG. 9 is a diagram illustrating a transmitting coil module and a receiving coil module according to one example embodiment.

FIG. 10 is a diagram illustrating a transmitting coil module and a receiving coil module according to one example embodiment.

FIG. 11 is a diagram illustrating a transmitting coil module and a receiving coil module according to one example embodiment.

FIG. 12 is a graph illustrating impedance characteristics of a receiving coil module according to one example embodiment.

FIG. 13 is a diagram illustrating an RF filter according to one example embodiment.

FIG. 14 is a diagram illustrating a rectifying and smoothing circuit according to one example embodiment.

FIG. 15 is a diagram illustrating an RF filter according to one example embodiment.

FIG. 16 is a diagram illustrating a communication device of a power transmitter and a communication device of a rectifying and smoothing circuit according to one example embodiment.

FIG. 17 is a diagram schematically illustrating a plasma processing apparatus according to yet another example embodiment.

FIG. 18 is a diagram schematically illustrating a plasma processing apparatus according to yet another example embodiment.

FIG. 19 is a diagram illustrating a communication device of a power transmitter and a communication device of a rectifying and smoothing circuit according to another example embodiment.

FIG. 20 is a diagram schematically illustrating a plasma processing apparatus according to yet another example embodiment.

FIG. 21 is a diagram schematically illustrating a plasma processing apparatus according to yet another example embodiment.

FIG. 22 is a diagram schematically illustrating a plasma processing apparatus according to yet another example embodiment.

Each of FIG. 23A and FIG. 23B is a diagram illustrating an energy storage according to one example embodiment.

FIG. 24 is a diagram illustrating a voltage control converter according to one example embodiment.

FIG. 25 is a diagram illustrating a constant voltage controller according to one example embodiment.

FIG. 26 is a diagram illustrating a constant voltage controller according to another example embodiment.

FIG. 27 is a diagram schematically illustrating a plasma processing apparatus according to yet another example embodiment.

FIG. 28 is a diagram schematically illustrating a plasma processing apparatus according to yet another example embodiment.

FIG. 29 is a diagram illustrating a transmitting coil module and a receiving coil module that may be employed in a plasma processing apparatus according to yet another example embodiment.

FIG. 30 is a diagram illustrating a transmitting coil module and a receiving coil module that may be employed in a plasma processing apparatus according to yet another example embodiment.

FIG. 31 is a diagram illustrating a receiving coil module that may be employed in a plasma processing apparatus according to yet another example embodiment.

FIG. 32 is a diagram illustrating a transmitting coil module and a receiving coil module that may be employed in a plasma processing apparatus according to yet another example embodiment.

FIG. 33 is a diagram illustrating a transmitting coil module and a receiving coil module that may be employed in a plasma processing apparatus according to yet another example embodiment.

FIG. 34 is a diagram illustrating a transmitting coil module and a receiving coil module that may be employed in a plasma processing apparatus according to yet another example embodiment.

FIG. 35 is a diagram illustrating a transmitting coil module and a receiving coil module that may be employed in a plasma processing apparatus according to yet another example embodiment.

FIG. 36 is a diagram schematically illustrating a plasma processing apparatus according to yet another example embodiment.

FIG. 37 is a diagram illustrating an equivalent circuit of an example of a transmitting coil module and a receiving coil module.

FIG. 38 is a diagram illustrating an example of at least one table.

FIG. 39 is a diagram illustrating an example of at least one table.

FIG. 40 is a diagram schematically illustrating a plasma processing apparatus according to yet another example embodiment.

FIG. 41 is a diagram illustrating a transmitting coil module and a receiving coil module that may be employed in a plasma processing apparatus according to yet another example embodiment.

FIG. 42 is a diagram illustrating a transmitting coil module and a receiving coil module that may be employed in a plasma processing apparatus according to yet another example embodiment.

FIG. 43 is a diagram schematically illustrating a plasma processing apparatus according to yet another example embodiment.

FIG. 44 is a diagram illustrating a transmitting coil module and a receiving coil module that may be employed in a plasma processing apparatus according to yet another example embodiment.

FIG. 45 is a diagram illustrating a transmitting coil module and a receiving coil module in a plasma processing apparatus according to yet another example embodiment.

FIG. 46 is a diagram illustrating a transmitting coil module and a receiving coil module in a plasma processing apparatus according to yet another example embodiment.

FIG. 47 is a diagram schematically illustrating a plasma processing apparatus according to yet another example embodiment.

FIG. 48 is a diagram schematically illustrating a plasma processing apparatus according to yet another example embodiment.

FIG. 49 is a diagram illustrating an immittance converter in a plasma processing apparatus according to yet another example embodiment.

FIG. 50 is a diagram illustrating a power transmitter that may be employed in plasma processing apparatuses according to various example embodiments.

FIG. 51 is a diagram for explaining adjustment of a duty of a transmission voltage of a power transmitter that may be employed in plasma processing apparatuses according to various example embodiments.

FIG. 52 is a diagram illustrating a power transmitter and an AC/DC converter that may be employed in plasma processing apparatuses according to various example embodiments.

FIG. 53 is a diagram illustrating a receiving coil module that may be employed in plasma processing apparatuses according to various example embodiments.

FIG. 54 is a diagram illustrating configurations of a receiving coil module and a rectifying and smoothing circuit that may be employed in plasma processing apparatuses according to various example embodiments.

FIG. 55 is a diagram illustrating configurations of a receiving coil module and a rectifying and smoothing circuit that may be employed in plasma processing apparatuses according to various example embodiments.

FIG. 56 is a diagram illustrating an integrated configuration related to power supply that may be employed in plasma processing apparatuses according to various example embodiments.

FIG. 57 is a diagram illustrating an integrated configuration related to power supply that may be employed in plasma processing apparatuses according to various example embodiments.

FIG. 58 is a diagram illustrating an integrated configuration related to power supply that may be employed in plasma processing apparatuses according to various example embodiments.

FIG. 59 is a diagram illustrating an integrated configuration related to power supply that may be employed in plasma processing apparatuses according to various example embodiments.

FIG. 60 is a diagram illustrating an integrated configuration related to power supply that may be employed in plasma processing apparatuses according to various example embodiments.

FIG. 61 is a diagram illustrating an integrated configuration related to power supply that may be employed in plasma processing apparatuses according to various example embodiments.

FIG. 62 is a diagram illustrating an integrated configuration related to power supply that may be employed in plasma processing apparatuses according to various example embodiments.

FIG. 63 is a diagram illustrating an integrated configuration related to power supply that may be employed in plasma processing apparatuses according to various example embodiments.

### DETAILED DESCRIPTION

Hereinafter, various example embodiments will be described in detail with reference to the drawings. In the drawings, the same or equivalent portions are denoted by the same reference signs.

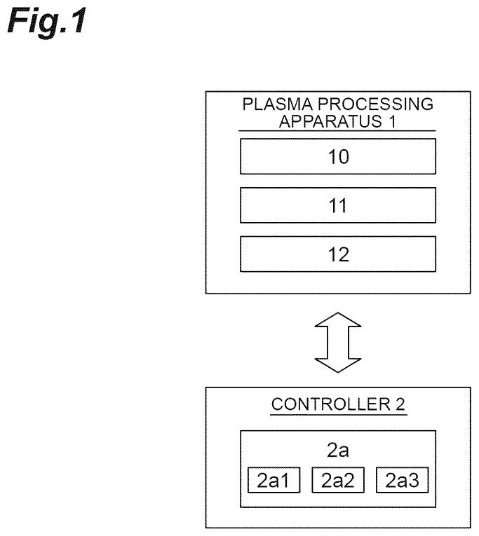

FIG. 1 illustrates an example configuration of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below, and the gas outlet is connected to a gas exhaust system 40 described below. The substrate support 11 is disposed in the plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, an AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, a part or all of the controller 2 may be incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads the program from the storage 2a2 to execute the program. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 may communicate with the plasma processing apparatus 1 via a communication line, such as a local area network (LAN).

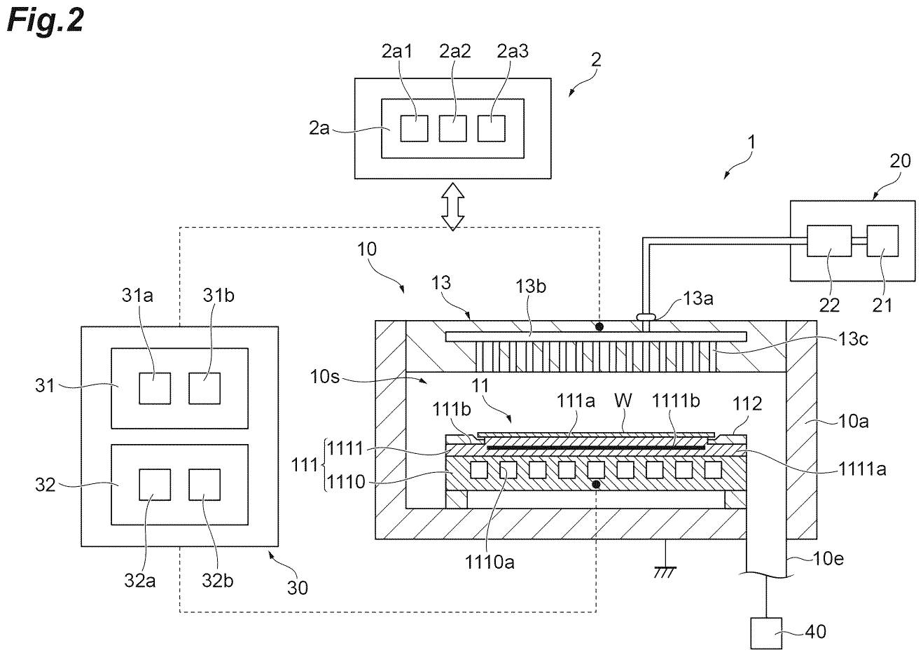

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in the plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode (also referred to as an adsorption electrode, a chuck electrode, or a clamp electrode) 1111b disposed in the ceramic member 1111a. The ceramic member 1111a has the central region 111a. In an embodiment, the ceramic member 1111a also has the annular region 111b. Any other member, such as an annular electrostatic chuck or an annular insulating member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or a DC signal described below are supplied to the at least one RF/DC electrode, the RF/DC electrode is also called a bias electrode. It is noted that the conductive member of the base 1110 and the at least one RF/DC electrode may function as a plurality of lower electrodes. The electrostatic electrode 1111b may also function as a lower electrode. The substrate support 11 accordingly includes at least one lower electrode.

The ring assembly 112 includes one or more annular members. In an embodiment, the one or more annular members include one or more edge rings and at least one cover ring. The one or more edge rings are composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may include a heater, a heat transfer medium, a flow passage 1110a, or any combination thereof. A heat transfer fluid, such as brine or gas, flows into the flow passage 1110a. In an embodiment, the flow passage 1110a is formed in the base 1110, and one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors (SGIs) provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may include, for example, a mass flow controller or a pressure-controlled flow controller. The gas supply 20 may include at least one flow modulation device that can modulate or pulse the flow of the at least one process gas.

The electric power source 30 includes an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses may have a rectangular, trapezoidal, or triangular waveform, or a combined waveform thereof. In an embodiment, a waveform generator for generating a sequence of voltage pulses from the DC signal is connected between the first DC generator 32a and the at least one lower electrode. The first DC generator 32a and the waveform generator thereby function as a voltage pulse generator. In the case that the second DC generator 32b and the waveform generator function as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may include a turbo-molecular pump, a dry pump, or a combination thereof.

In the capacitively coupled plasma processing apparatus 1, the upper electrode is disposed such that the plasma processing space is located between the upper electrode and the substrate support 11. A radio frequency power supply such as the first RF generator 31a is electrically connected to the upper electrode or the lower electrode in the substrate support 11. When the plasma processing apparatus 1 is an inductively coupled plasma processing apparatus, an antenna is disposed such that the plasma processing space is located between the antenna and the substrate support 11. A radio frequency power supply such as the first RF generator 31a is electrically connected to the antenna. When the plasma processing apparatus 1 is a plasma processing apparatus that generates plasma by a surface wave such as a microwave, an antenna is disposed such that the plasma processing space is located between the antenna and the substrate support 11. A radio frequency power supply such as the first RF generator 31a is electrically connected to the antenna via a waveguide.

Hereinafter, plasma processing apparatuses according to various example embodiments will be described. Each plasma processing apparatus described below is configured to supply power to at least one power consuming member (or at least one load) in the chamber 10 by wireless power supply (electromagnetic induction coupling), and may have the same configuration as the plasma processing apparatus 1.

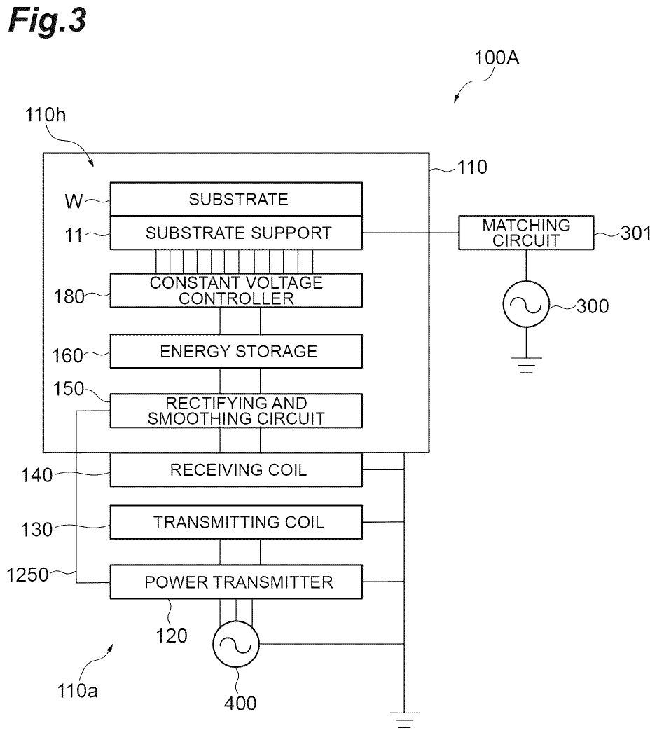

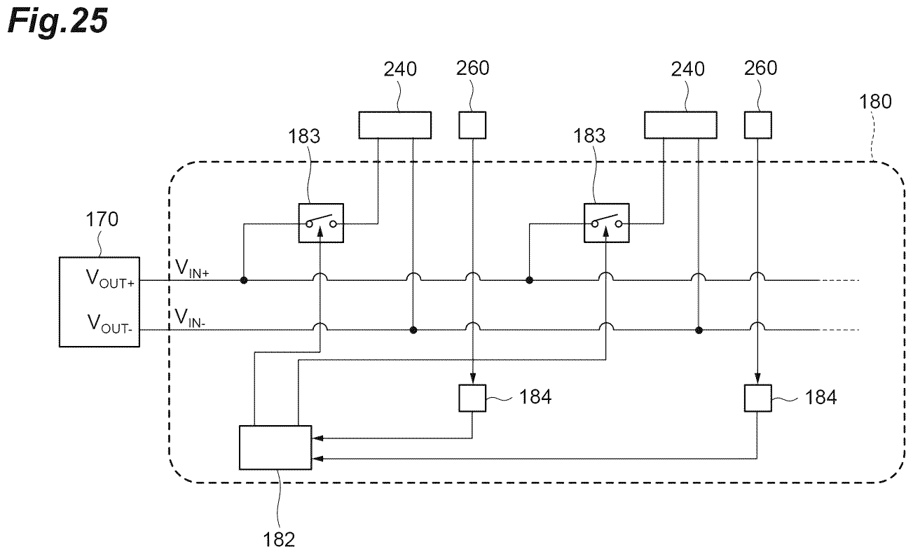

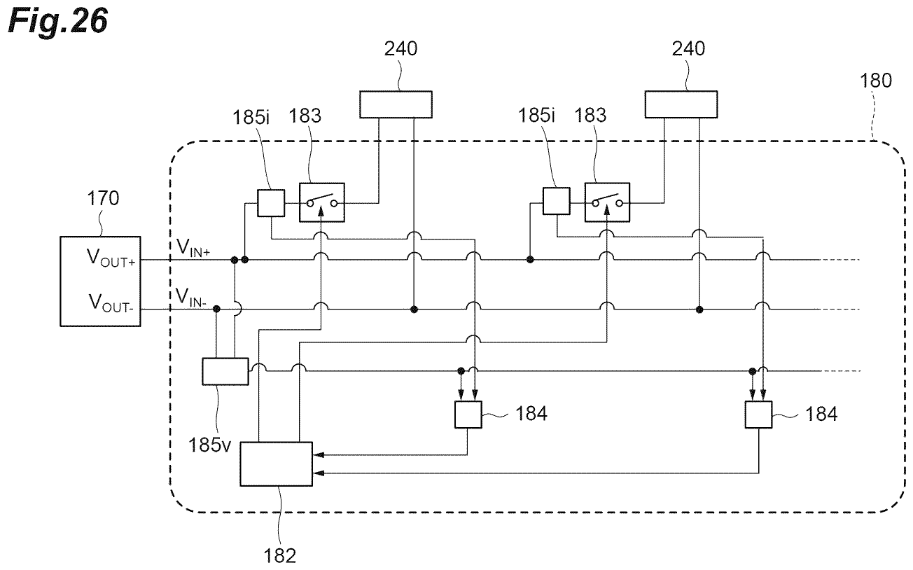

FIG. 3 is a diagram schematically illustrating a plasma processing apparatus according to one example embodiment. The plasma processing apparatus 100A illustrated in FIG. 3 includes at least one radio frequency power supply 300, a receiving coil module 140, an energy storage 160, and at least one power consuming member 240 which is at least one load (see FIGS. 25 and 26). The plasma processing apparatus 100A may further include a power transmitter 120, a transmitting coil module 130, a rectifying and smoothing circuit 150, a constant voltage controller 180 (an example of a voltage controller), a ground frame 110, and a matching circuit 301.

The at least one radio frequency power supply 300 includes the first RF generator 31a and/or the second RF generator 31b. The at least one radio frequency power supply 300 is electrically connected to the substrate support 11 via the matching circuit 301. The matching circuit 301 includes at least one impedance matching circuit.

The ground frame 110 includes the chamber 10 and is electrically grounded. The ground frame 110 electrically separates an interior space 110h (RF-Hot space) thereof from an exterior space 110a (atmospheric space). The ground frame 110 surrounds the substrate support 11 disposed in the space 110h. In the plasma processing apparatus 100A, the rectifying and smoothing circuit 150, the energy storage 160, and the constant voltage controller 180 are disposed in the space 110h. In the plasma processing apparatus 100A, the power transmitter 120, the transmitting coil module 130, and the receiving coil module 140 are disposed in the space 110a. The space 110h includes a reduced-pressure space (vacuum space) and a non-reduced-pressure space (non-vacuum space). The reduced-pressure space is a space inside the chamber 10, and the non-reduced-pressure space is a space outside the chamber 10. The substrate support 11 and the substrate W are disposed in the reduced-pressure space. The rectifying and smoothing circuit 150, the energy storage 160, and the constant voltage controller 180 are disposed in the non-reduced-pressure space.

The devices disposed in the space 110a, namely the power transmitter 120, the transmitting coil module 130, the receiving coil module 140, and the like, are covered by a metal housing formed of a metal such as aluminum, and the metal housing is grounded. This suppresses leakage of radio frequency noise caused by radio frequency power such as the first RF signal (source RF signal) and/or the second RF signal (bias RF signal). The metal housing and each power supply line have an insulation distance therebetween. In the following description, radio frequency power such as the first RF signal and/or the second RF signal that propagates toward the power transmitter 120 may be referred to as radio frequency noise, common mode noise, or conducted noise.

The power transmitter 120 is electrically connected between an AC power source 400 (for example, a commercial AC power source) and the transmitting coil module 130. The power transmitter 120 receives AC power from the AC power source 400 and converts the frequency of the AC power into a transmission frequency, thereby generating AC power having the transmission frequency, that is, transmission AC power.

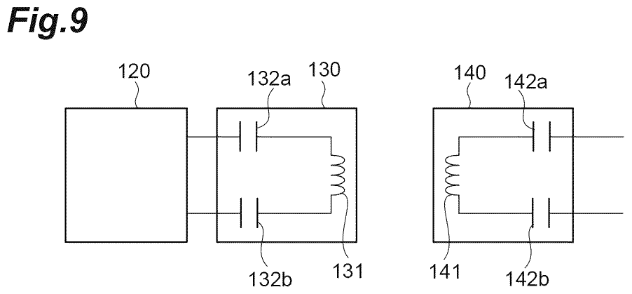

The transmitting coil module 130 includes a transmitting coil 131 (see FIG. 9) described below. The transmitting coil 131 is electrically connected to the power transmitter 120. The transmitting coil 131 receives the transmission AC power from the power transmitter 120 and wirelessly transmits the transmission AC power to the receiving coil 141.

The receiving coil module 140 includes a receiving coil 141 (see FIG. 9) described below. The receiving coil 141 is electromagnetically inductively coupled to the transmitting coil 131. Electromagnetic induction coupling includes magnetic field coupling and electric field coupling. Magnetic field coupling also includes magnetic resonance (also referred to as magnetic field resonance). The distance between the receiving coil 141 and the transmitting coil 131 is set so as to suppress common mode noise (conducted noise). The distance between the receiving coil 141 and the transmitting coil 131 is also set to a distance at which power can be supplied. The distance between the receiving coil 141 and the transmitting coil 131 is set such that the attenuation of radio frequency power (i.e., radio frequency noise) between the receiving coil 141 and the transmitting coil 131 is equal to or less than a threshold value, and such that power from the transmitting coil 131 can be received by the receiving coil 141. The threshold value of the attenuation is set to a value that can sufficiently prevent damage or malfunction of the power transmitter 120. The threshold value of the attenuation is, for example, −20 dB. The transmission AC power received by the receiving coil module 140 is output to the rectifying and smoothing circuit 150.

The rectifying and smoothing circuit 150 is electrically connected between the receiving coil module 140 and the energy storage 160. The rectifying and smoothing circuit 150 generates DC power by full-wave rectification and smoothing of the transmission AC power from the receiving coil module 140. The DC power generated by the rectifying and smoothing circuit 150 is stored in the energy storage 160. The energy storage 160 is electrically connected between the rectifying and smoothing circuit 150 and the constant voltage controller 180. The rectifying and smoothing circuit 150 may generate DC power by half-wave rectification and smoothing of the transmission AC power from the receiving coil module 140.

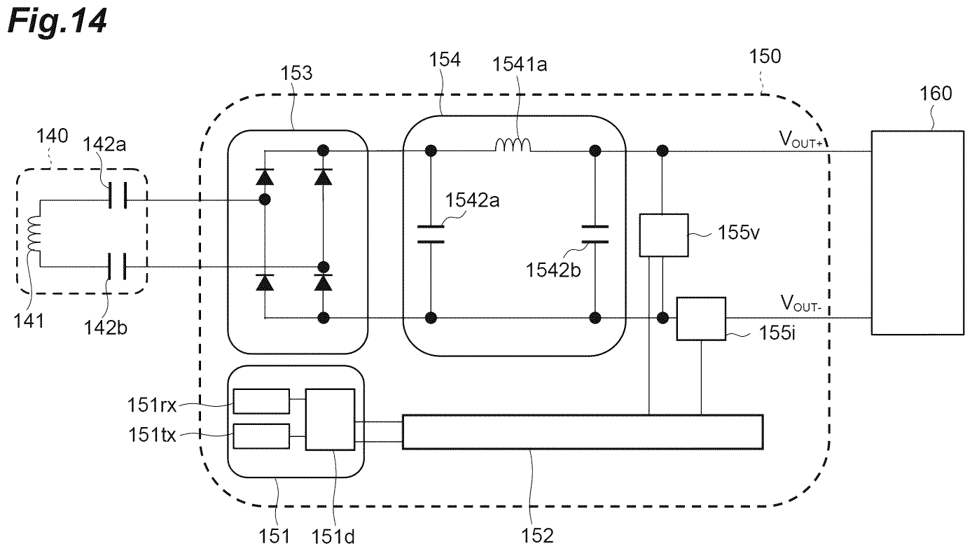

The rectifying and smoothing circuit 150 and the power transmitter 120 are electrically connected to each other by a signal line 1250. The rectifying and smoothing circuit 150 transmits an instruction signal to the power transmitter 120 via the signal line 1250. The instruction signal is a signal for instructing the power transmitter 120 to supply the transmission AC power or to stop the supply of the transmission AC power. The instruction signal may include a status signal, an abnormality detection signal, and a cooling control signal for the transmitting coil module 130 and the receiving coil module 140. The status signal is a value such as the magnitude and/or phase of voltage, current, and power detected by a voltage detector 155v (see FIG. 14) and a current detector 155i (see FIG. 14) of the rectifying and smoothing circuit 150. The abnormality detection signal is a signal for notifying the power transmitter 120 of the occurrence of a failure and/or a temperature abnormality of the rectifying and smoothing circuit 150. The cooling control signal controls cooling mechanisms provided in the transmitting coil module 130 and the receiving coil module 140. The cooling control signal controls, for example, the rotation speed of a cooling mechanism such as a fan or a blower in the case of air cooling. In the case of liquid cooling, the cooling control signal controls the flow velocity and/or temperature, or the like of the refrigerant.

The constant voltage controller 180 applies a voltage to at least the power consuming member 240 using the power stored in the energy storage 160. The constant voltage controller 180 can control the application of a voltage to at least the power consuming member 240 and the stopping thereof.

In the plasma processing apparatus 100A, the receiving coil 141 functions as a filter against radio frequency noise caused by radio frequency power such as the first RF signal and/or the second RF signal. Therefore, propagation of radio frequency noise to a power source external to the plasma processing apparatus is suppressed.

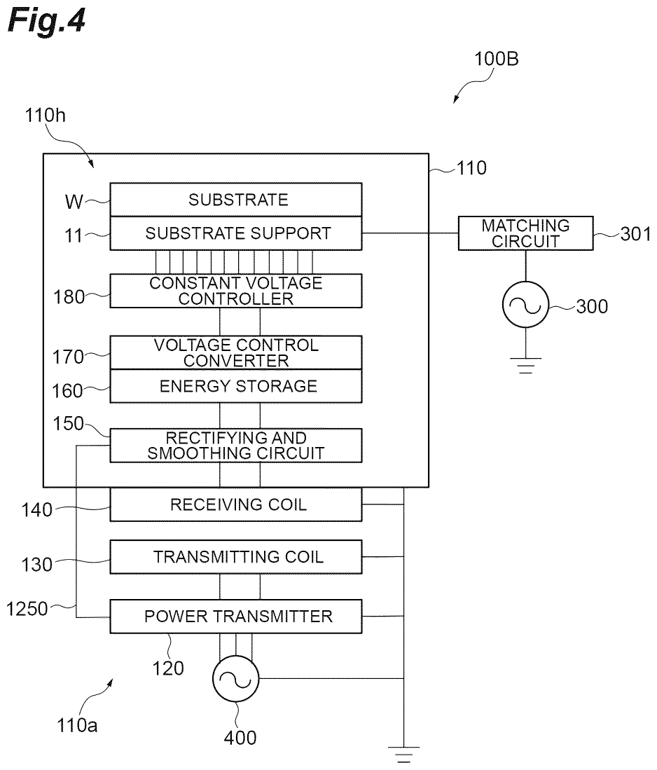

Reference is made to FIG. 4. FIG. 4 is a diagram schematically illustrating a plasma processing apparatus according to another example embodiment. Hereinafter, the plasma processing apparatus 100B illustrated in FIG. 4 will be described from the perspective of its differences from the plasma processing apparatus 100A.

The plasma processing apparatus 100B further includes a voltage control converter 170. The voltage control converter 170 is a DC-DC converter and is connected between the energy storage 160 and the constant voltage controller 180. The voltage control converter 170 may be configured to input a constant output voltage to the constant voltage controller 180 even when a voltage fluctuation occurs in the energy storage 160. The voltage fluctuation in the energy storage 160 may occur, for example, as a voltage drop or the like corresponding to the stored power when the energy storage 160 is configured with an electric double layer capacitor.

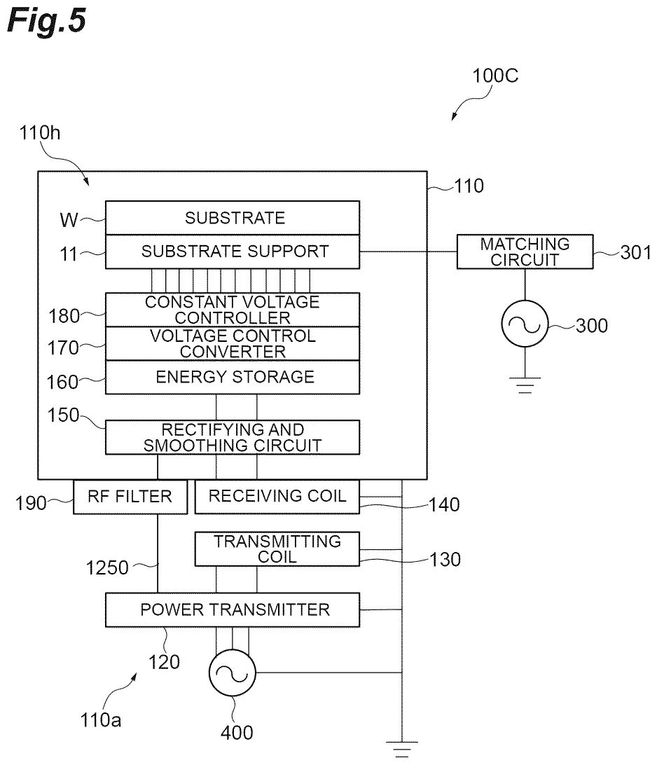

Reference is made to FIG. 5. FIG. 5 is a diagram schematically illustrating a plasma processing apparatus according to yet another example embodiment. Hereinafter, the plasma processing apparatus 100C illustrated in FIG. 5 will be described from the perspective of its differences from the plasma processing apparatus 100B.

The plasma processing apparatus 100C further includes an RF filter 190. The RF filter 190 is connected between the rectifying and smoothing circuit 150 and the power transmitter 120. The RF filter 190 provides a part of the signal line 1250. The RF filter 190 has a characteristic of suppressing propagation of radio frequency power (radio frequency noise) via the signal line 1250. That is, the RF filter 190 includes a low-pass filter having a characteristic of having high impedance against radio frequency noise (conducted noise) but passing an instruction signal of a relatively low frequency.

In the plasma processing apparatus 100C, the energy storage 160, the voltage control converter 170, and the constant voltage controller 180 are integrated with each other. That is, the energy storage 160, the voltage control converter 170, and the constant voltage controller 180 are all disposed in a single metal housing or formed on a single circuit board. This shortens the length of each of a pair of power supply lines (a plus line and a minus line) connecting the energy storage 160 and the voltage control converter 170 to each other. It is also possible to make the lengths of the pair of power supply lines connecting the energy storage 160 and the voltage control converter 170 to each other equal to each other. Also, the length of each of a pair of power supply lines (a plus line and a minus line) connecting the voltage control converter 170 and the constant voltage controller 180 to each other is shortened. It is also possible to make the lengths of the pair of power supply lines connecting the voltage control converter 170 and the constant voltage controller 180 to each other equal to each other. Therefore, malfunction and damage of devices caused by normal mode noise (potential difference between the plus line and the minus line) are suppressed. When another metal body that shields an electromagnetic field around the housing is provided in the chamber 10, the single housing need not be made of metal.

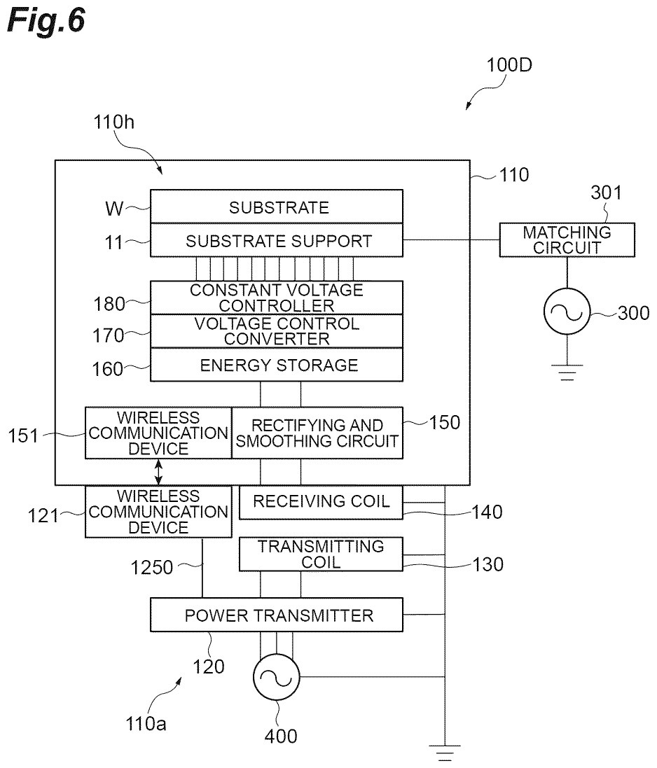

Reference is made to FIG. 6. FIG. 6 is a diagram schematically illustrating a plasma processing apparatus according to yet another example embodiment. Hereinafter, the plasma processing apparatus 100D illustrated in FIG. 6 will be described from the perspective of its differences from the plasma processing apparatus 100C.

The plasma processing apparatus 100D does not include the RF filter 190. In the plasma processing apparatus 100D, the rectifying and smoothing circuit 150 includes a communication device 151 that is a wireless communication device. The communication device 151 is disposed in the non-reduced-pressure space. The power transmitter 120 also includes a communication device 121 that is a wireless communication device. The communication device 121 is disposed in the space 110a. The above-described instruction signal is transmitted between the rectifying and smoothing circuit 150 and the power transmitter 120 using the communication device 151 and the communication device 121. Details of the communication device 121 and the communication device 151 will be described below.

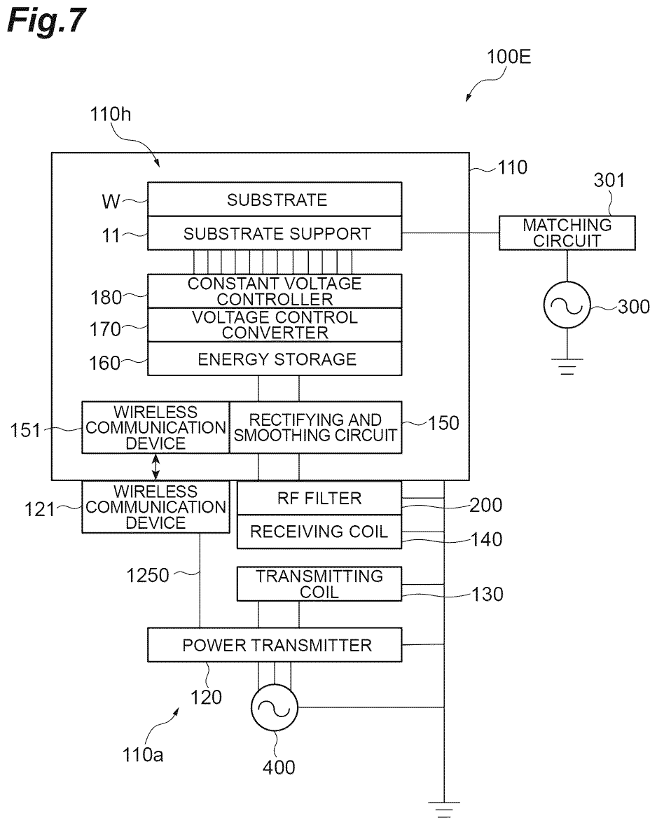

Reference is made to FIG. 7. FIG. 7 is a diagram schematically illustrating a plasma processing apparatus according to yet another example embodiment. Hereinafter, the plasma processing apparatus 100E illustrated in FIG. 7 will be described from the perspective of its differences from the plasma processing apparatus 100D.

The plasma processing apparatus 100E further includes an RF filter 200. The RF filter 200 is connected between the receiving coil module 140 and the rectifying and smoothing circuit 150. The RF filter 200 has a characteristic of reducing or blocking radio frequency noise propagating from the receiving coil module 140 to the transmitting coil 131 and the power transmitter 120. Details of the RF filter 200 will be described below.

Hereinafter, the configuration of each component for wireless power supply in the plasma processing apparatuses according to various example embodiments will be described in detail.

### Configuration of Power Transmitter

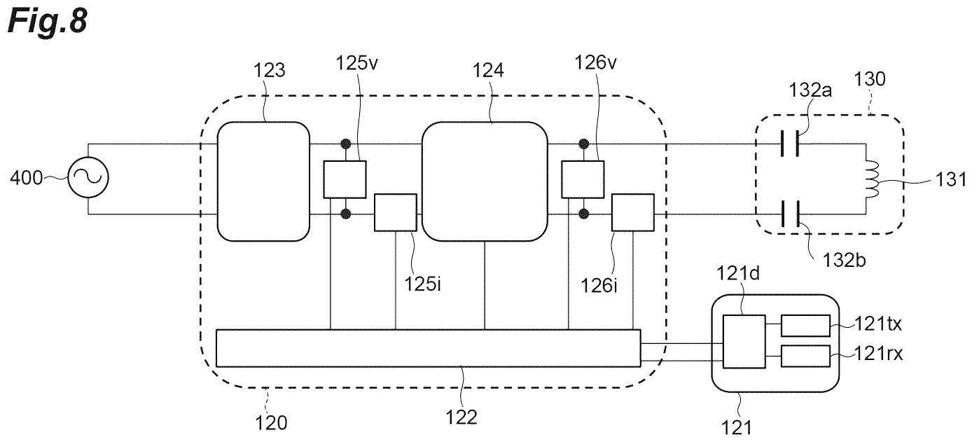

FIG. 8 is a diagram illustrating a power transmitter according to one example embodiment. As described above, the power transmitter 120 receives AC power from the AC power source 400 and converts the frequency of the AC power into a transmission frequency, thereby generating transmission AC power having the transmission frequency.

In one embodiment, the power transmitter 120 includes a controller 122, a rectifying and smoothing circuit 123, and an inverter 124. The controller 122 includes a processor such as a CPU or a programmable logic device such as an FPGA (Field-Programmable Gate Array).

The rectifying and smoothing circuit 123 includes a rectifier circuit and a smoothing circuit. The rectifier circuit includes, for example, a diode bridge. The smoothing circuit includes, for example, a line capacitor. The rectifying and smoothing circuit 123 generates DC power by full-wave rectification and smoothing of the AC power from the AC power source 400. The rectifying and smoothing circuit 123 may generate DC power by half-wave rectification and smoothing of the AC power from the AC power source 400.

The inverter 124 generates transmission AC power having a transmission frequency from the DC power output by the rectifying and smoothing circuit 123. The inverter 124 is, for example, a full-bridge inverter and includes a plurality of triacs or a plurality of switching elements (for example, FETs). The inverter 124 generates the transmission AC power by ON/OFF control of the plurality of triacs or the plurality of switching elements by the controller 122. The transmission AC power output from the inverter 124 is output to the transmitting coil module 130.

The power transmitter 120 may further include a voltage detector 125v, a current detector 125i, a voltage detector 126v, and a current detector 126i. The voltage detector 125v detects a voltage value between a pair of power supply lines connecting the rectifying and smoothing circuit 123 and the inverter 124 to each other. The current detector 125i detects a current value between the rectifying and smoothing circuit 123 and the inverter 124. The voltage detector 126v detects a voltage value between a pair of power supply lines connecting the inverter 124 and the transmitting coil module 130 to each other. The current detector 126i detects a current value between the inverter 124 and the transmitting coil module 130. The voltage value detected by the voltage detector 125v, the current value detected by the current detector 125i, the voltage value detected by the voltage detector 126v, and the current value detected by the current detector 126i are notified to the controller 122.

The power transmitter 120 includes the above-described communication device 121. The communication device 121 includes a driver 121d, a transmitter 121tx, and a receiver 121rx. The transmitter 121tx is a transmitter of a wireless signal or a transmitter of an optical signal. The receiver 121rx is a receiver of a wireless signal or a receiver of an optical signal. The communication device 121 drives the transmitter 121tx by the driver 121d to cause the transmitter 121tx to output a signal from the controller 122 as a wireless signal or an optical signal. The signal output from the transmitter 121tx is received by the communication device 151 (see FIG. 14) described below. The communication device 121 also receives a signal such as the above-described instruction signal from the communication device 151 by the receiver 121rx and inputs the received signal to the controller 122 via the driver 121d. The controller 122 controls the inverter 124 in accordance with the instruction signal received from the communication device 151 via the communication device 121, the voltage value detected by the voltage detector 125v, the current value detected by the current detector 125i, the voltage value detected by the voltage detector 126v, and the current value detected by the current detector 126i, thereby switching between output of the transmission AC power and stopping thereof.

### Transmitting Coil Module and Receiving Coil Module

Reference is made to FIGS. 9 to 11. Each of FIGS. 9 to 11 is a diagram illustrating a transmitting coil module and a receiving coil module according to one example embodiment. As illustrated in FIG. 9, the transmitting coil module 130 may include, in addition to the transmitting coil 131, a resonance capacitor 132a and a resonance capacitor 132b. The resonance capacitor 132a is connected between one of a pair of power supply lines connecting the power transmitter 120 and the transmitting coil module 130 to each other and one end of the transmitting coil 131. The resonance capacitor 132b is connected between the other of the pair of power supply lines and the other end of the transmitting coil 131. The transmitting coil 131, the resonance capacitor 132a, and the resonance capacitor 132b form a resonance circuit for the transmission frequency. That is, the transmitting coil 131, the resonance capacitor 132a, and the resonance capacitor 132b have a resonance frequency that substantially matches the transmission frequency. The transmitting coil module 130 may omit either one of the resonance capacitor 132a and the resonance capacitor 132b.

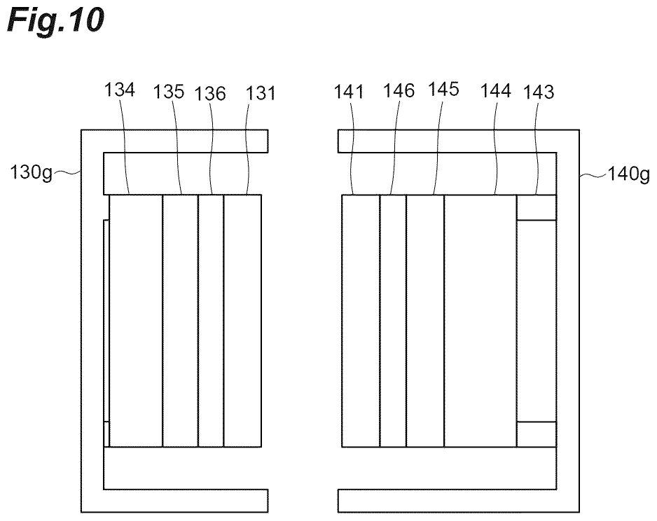

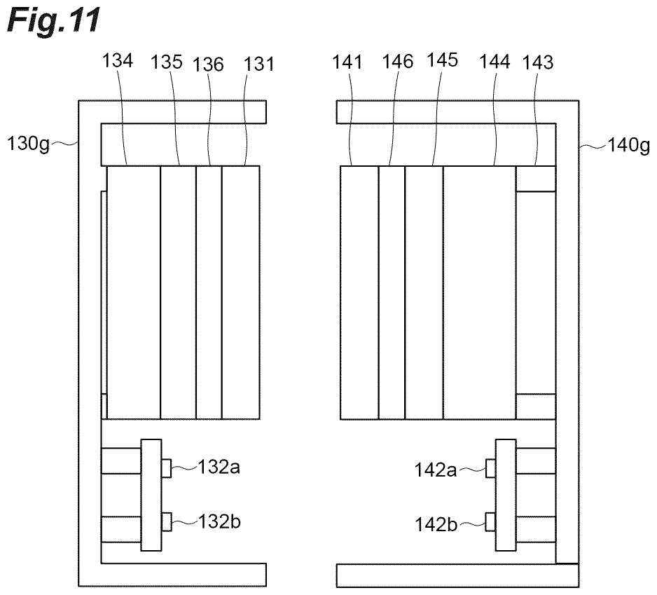

As illustrated in FIGS. 10 and 11, the transmitting coil module 130 may further include a metal housing 130g. The metal housing 130g has an open end and is grounded. The transmitting coil 131 is disposed in the metal housing 130g with an insulation distance secured. The transmitting coil module 130 may further include a heat sink 134, a ferrite member 135, and a thermal conductive sheet 136. The heat sink 134 is disposed in the metal housing 130g and is supported by the metal housing 130g. The ferrite member 135 is disposed on the heat sink 134. The thermal conductive sheet 136 is disposed on the ferrite member 135. The transmitting coil 131 is disposed on the thermal conductive sheet 136 and faces the receiving coil 141 through the open end of the metal housing 130g. As illustrated in FIG. 11, the resonance capacitor 132a and the resonance capacitor 132b may further be accommodated in the metal housing 130g.

As illustrated in FIG. 9, the receiving coil module 140 includes a receiving coil 141. The receiving coil 141 is coupled to the transmitting coil 131 by electromagnetic induction. The receiving coil module 140 may include, in addition to the receiving coil 141, a resonance capacitor 142a and a resonance capacitor 142b. The resonance capacitor 142a is connected between one of a pair of power supply lines extending from the receiving coil module 140 and one end of the receiving coil 141. The resonance capacitor 142b is connected between the other of the pair of power supply lines and the other end of the receiving coil 141. The receiving coil 141, the resonance capacitor 142a, and the resonance capacitor 142b form a resonance circuit for the transmission frequency. That is, the receiving coil 141, the resonance capacitor 142a, and the resonance capacitor 142b have a resonance frequency that substantially matches the transmission frequency. The receiving coil module 140 may omit either one of the resonance capacitor 142a and the resonance capacitor 142b.

As illustrated in FIGS. 10 and 11, the receiving coil module 140 may further include a metal housing 140g. The metal housing 140g has an open end and is grounded. The receiving coil 141 is disposed in the metal housing 140g with an insulation distance secured. The receiving coil module 140 may further include a spacer 143, a heat sink 144, a ferrite member 145, and a thermal conductive sheet 146. The spacer 143 is disposed in the metal housing 140g and is supported by the metal housing 140g. The spacer 143 will be described below. The heat sink 144 is disposed on the spacer 143. The ferrite member 145 is disposed on the heat sink 144. The thermal conductive sheet 146 is disposed on the ferrite member 145. The receiving coil 141 is disposed on the thermal conductive sheet 146 and faces the transmitting coil 131 through the open end of the metal housing 140g. As illustrated in FIG. 11, the resonance capacitor 142a and the resonance capacitor 142b may further be accommodated in the metal housing 140g.

The spacer 143 is formed of a dielectric material and is provided between the receiving coil 141 and the metal housing 140g (ground). The spacer 143 provides a stray capacitance in a space between the receiving coil 141 and the ground.

### Impedance Characteristics of Receiving Coil Module

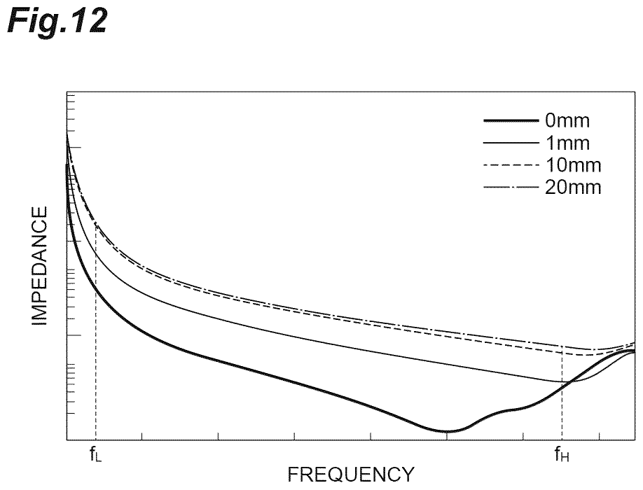

Reference is made to FIG. 12. FIG. 12 is a graph illustrating impedance characteristics of a receiving coil module according to one example embodiment. FIG. 12 illustrates the impedance characteristics of the receiving coil module 140 according to the thickness of the spacer 143. The thickness of the spacer 143 corresponds to the distance between the heat sink 144 and the metal housing 140g. As illustrated in FIG. 12, the receiving coil module 140 can adjust the impedance at each of the frequency f_{H} and the frequency f_{L} according to the thickness of the spacer 143. Therefore, with the receiving coil module 140, high impedance can be provided at each of the frequencies of two radio frequency powers used in the plasma processing apparatus, such as the first RF signal and the second RF signal. In addition, since high impedance can be obtained in the receiving coil module 140, loss of radio frequency power can be suppressed, and a high processing rate (for example, etching rate) can be obtained.

### RF Filter 200

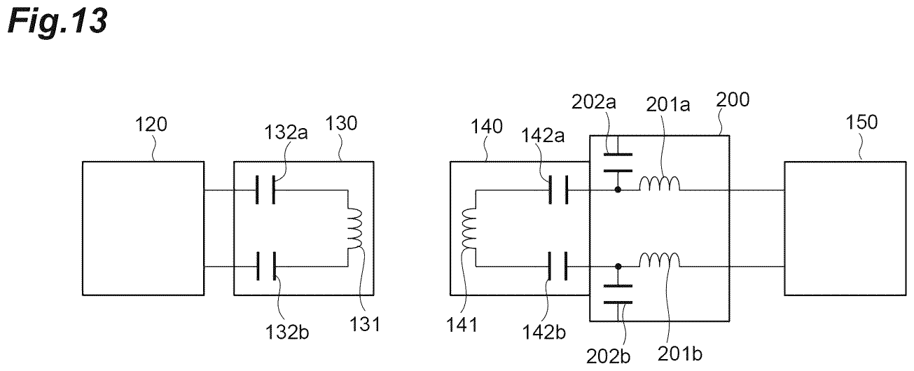

Reference is made to FIG. 13. FIG. 13 is a diagram illustrating an RF filter according to one example embodiment. As illustrated in FIG. 13, the RF filter 200 is connected between the receiving coil module 140 and the rectifying and smoothing circuit 150. The RF filter 200 includes an inductor 201a, an inductor 201b, a termination capacitor 202a, and a termination capacitor 202b. One end of the inductor 201a is connected to the resonance capacitor 142a, and the other end of the inductor 201a is connected to the rectifying and smoothing circuit 150. One end of the inductor 201b is connected to the resonance capacitor 142b, and the other end of the inductor 201b is connected to the rectifying and smoothing circuit 150. The termination capacitor 202a is connected between one end of the inductor 201a and ground. The termination capacitor 202b is connected between one end of the inductor 201b and ground. The inductor 201a and the termination capacitor 202a form a low-pass filter. The inductor 201b and the termination capacitor 202b also form a low-pass filter. With the RF filter 200, high impedance is obtained at each of the frequencies of two radio frequency powers used in the plasma processing apparatus, such as the first RF signal and the second RF signal. Therefore, loss of radio frequency power is suppressed, and a high processing rate (for example, etching rate) can be obtained.

### Rectifying and Smoothing Circuit

Reference is made to FIG. 14. FIG. 14 is a diagram illustrating a rectifying and smoothing circuit according to one example embodiment. In one embodiment, the rectifying and smoothing circuit 150 includes a controller 152, a rectifier circuit 153, and a smoothing circuit 154. The rectifier circuit 153 is connected between the receiving coil module 140 and the smoothing circuit 154. The smoothing circuit 154 is connected between the rectifier circuit 153 and the energy storage 160. The controller 152 includes a processor such as a CPU or a programmable logic device such as an FPGA (Field-Programmable Gate Array). The controller 152 may be the same as or different from the controller 122.

The rectifier circuit 153 outputs power generated by full-wave rectification of the AC power from the receiving coil module 140. The rectifier circuit 153 is, for example, a diode bridge. The rectifier circuit 153 may output power generated by half-wave rectification of the AC power from the receiving coil module 140.

The smoothing circuit 154 generates DC power by smoothing the power from the rectifier circuit 153. The smoothing circuit 154 may include an inductor 1541a, a capacitor 1542a, and a capacitor 1542b. One end of the inductor 1541a is connected to one of a pair of inputs of the smoothing circuit 154. The other end of the inductor 1541a is connected to a positive output (V_{OUT+}) of the rectifying and smoothing circuit 150. The positive output of the rectifying and smoothing circuit 150 is connected to one end of each of one or more capacitors of the energy storage 160 via a plus line 160p of a pair of power supply lines described below (see FIG. 23A and FIG. 23B).

One end of the capacitor 1542a is connected to one of the pair of inputs of the smoothing circuit 154 and one end of the inductor 1541a. The other end of the capacitor 1542a is connected to the other of a pair of outputs of the smoothing circuit 154 and a negative output (V_{OUT-}) of the rectifying and smoothing circuit 150. The negative output of the rectifying and smoothing circuit 150 is connected to the other end of each of the one or more capacitors of the energy storage 160 via a minus line 160m of the pair of power supply lines described below (see FIG. 23A and FIG. 23B). One end of the capacitor 1542b is connected to the other end of the inductor 1541a. The other end of the capacitor 1542b is connected to the other of the pair of outputs of the smoothing circuit 154 and the negative output (V_{OUT-}) of the rectifying and smoothing circuit 150.

The rectifying and smoothing circuit 150 may further include a voltage detector 155v and a current detector 155i. The voltage detector 155v detects a voltage value between the positive output and the negative output of the rectifying and smoothing circuit 150. The current detector 155i detects a current value between the rectifying and smoothing circuit 150 and the energy storage 160. The voltage value detected by the voltage detector 155v and the current value detected by the current detector 155i are notified to the controller 152. The controller 152 generates the above-described instruction signal in accordance with the power stored in the energy storage 160. For example, when the power stored in the energy storage 160 is equal to or less than a first threshold value, the controller 152 generates an instruction signal for instructing the power transmitter 120 to supply power, that is, to output the transmission AC power. The first threshold value is, for example, the power consumed by a load such as the power consuming member 240. The first threshold value may also be a value obtained by multiplying the power consumed by a load such as the power consuming member 240 by a constant value (for example, a value in a range of 1 or more and 3 or less) in consideration of a margin. On the other hand, when the power stored in the energy storage 160 is greater than a second threshold value, the controller 152 generates an instruction signal for instructing the power transmitter 120 to stop power supply, that is, to stop output of the transmission AC power. The second threshold value is a value that does not exceed the limit stored power of the energy storage 160. The second threshold value is, for example, a value obtained by multiplying the limit stored power of the energy storage 160 by a constant value (for example, a value of 1 or less).

The rectifying and smoothing circuit 150 includes the above-described communication device 151. The communication device 151 includes a driver 151d, a transmitter 151tx, and a receiver 151rx. The transmitter 151tx is a transmitter of a wireless signal or a transmitter of an optical signal. The receiver 151rx is a receiver of a wireless signal or a receiver of an optical signal. The communication device 151 drives the transmitter 151tx by the driver 151d to cause the transmitter 151tx to output a signal from the controller 152 such as an instruction signal as a wireless signal or an optical signal. The signal output from the transmitter 151tx is received by the communication device 121 of the power transmitter 120. The communication device 151 also receives a signal from the communication device 121 by the receiver 151rx and inputs the received signal to the controller 152 via the driver 151d.

### RF Filter 190

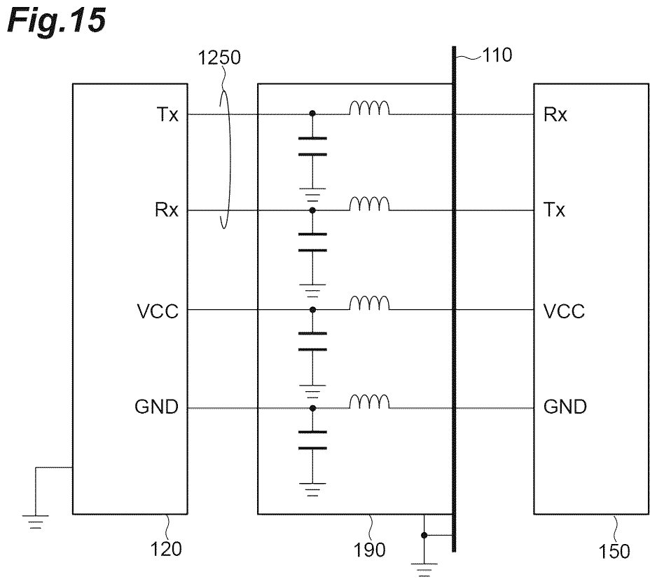

Reference is made to FIG. 15. FIG. 15 is a diagram illustrating an RF filter 190 according to one example embodiment. As illustrated in FIG. 15, the signal line 1250 may include a first signal line electrically connecting a signal output (Tx) of the power transmitter 120 and a signal input (Rx) of the rectifying and smoothing circuit 150, and a second signal line electrically connecting a signal input (Rx) of the power transmitter 120 and a signal output (Tx) of the rectifying and smoothing circuit 150. The signal line 1250 may include a signal line connecting a first reference voltage terminal (VCC) of the power transmitter 120 and a first reference voltage terminal (VCC) of the rectifying and smoothing circuit 150, and a signal line connecting a second reference voltage terminal (GND) of the power transmitter 120 and a second reference voltage terminal (GND) of the rectifying and smoothing circuit 150. The signal line 1250 may be a shielded cable covered with a shield at ground potential. In this case, the plurality of signal lines forming the signal line 1250 may be individually covered with a shield one by one, or may be collectively covered with a shield. The RF filter 190 provides a low-pass filter to each of the plurality of signal lines forming the signal line 1250. The low-pass filter may be an LC filter including an inductor and a capacitor. The inductor of the low-pass filter forms a part of the corresponding signal line. The capacitor is connected between one end of the inductor connected to the power transmitter 120 and ground. With the RF filter 190, propagation of radio frequency power (radio frequency noise) via the signal line 1250 between the rectifying and smoothing circuit 150 and the power transmitter 120 can be suppressed.

### Communication Device of Power Transmitter and Communication Device of Rectifying and Smoothing Circuit

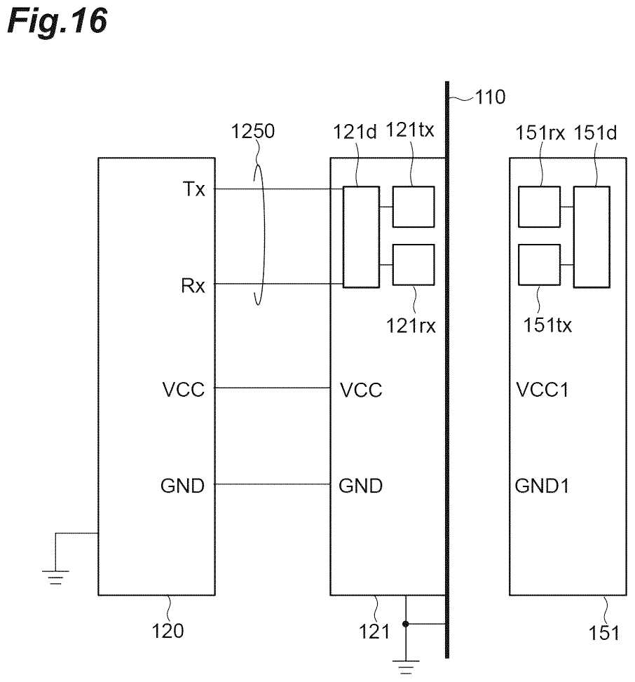

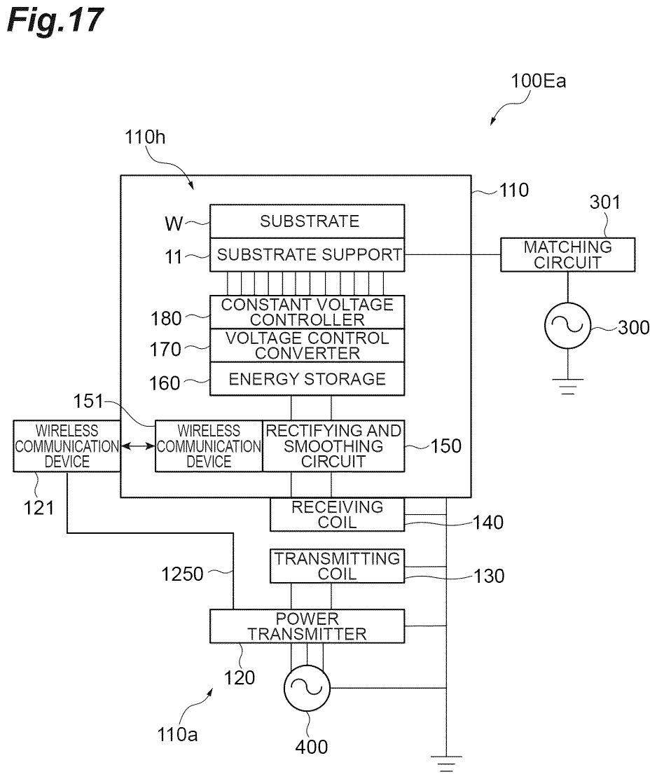

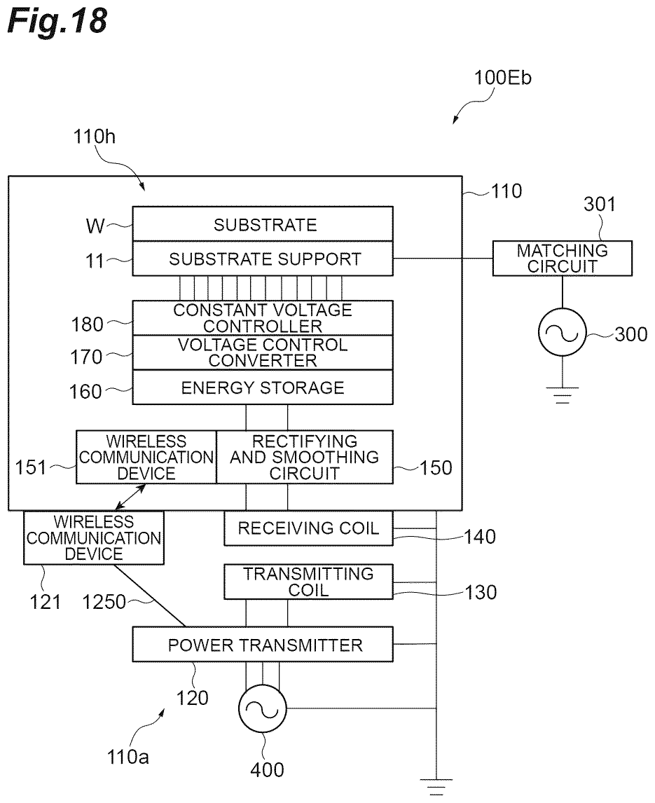

Reference is made to FIGS. 16 to 18. FIG. 16 is a diagram illustrating a communication device of a power transmitter and a communication device of a rectifying and smoothing circuit according to one example embodiment. Each of FIGS. 17 and 18 is a diagram schematically illustrating a plasma processing apparatus according to yet another example embodiment. As illustrated in FIGS. 6, 7, 16, 17, and 18, the communication device 121 and the communication device 151 may be configured to transmit a signal such as the above-described instruction signal between each other via wireless communication. Communication via wireless communication may be performed by optical communication. When the communication device 121 and the communication device 151 transmit signals between each other via wireless communication, the communication device 121 and the communication device 151 may be disposed at any position as long as no shielding object is interposed therebetween. In the examples illustrated in these figures, the RF filter 190 becomes unnecessary. In various example embodiments including the examples illustrated in FIGS. 16 to 18, the signal line 1250 may be a shielded cable covered with a shield at ground potential. In this case, the plurality of signal lines forming the signal line 1250 may be individually covered with a shield one by one, or may be collectively covered with a shield.

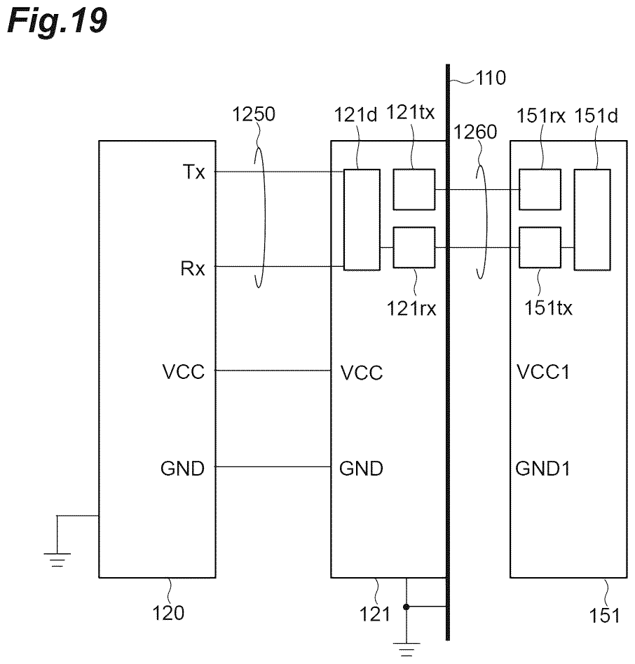

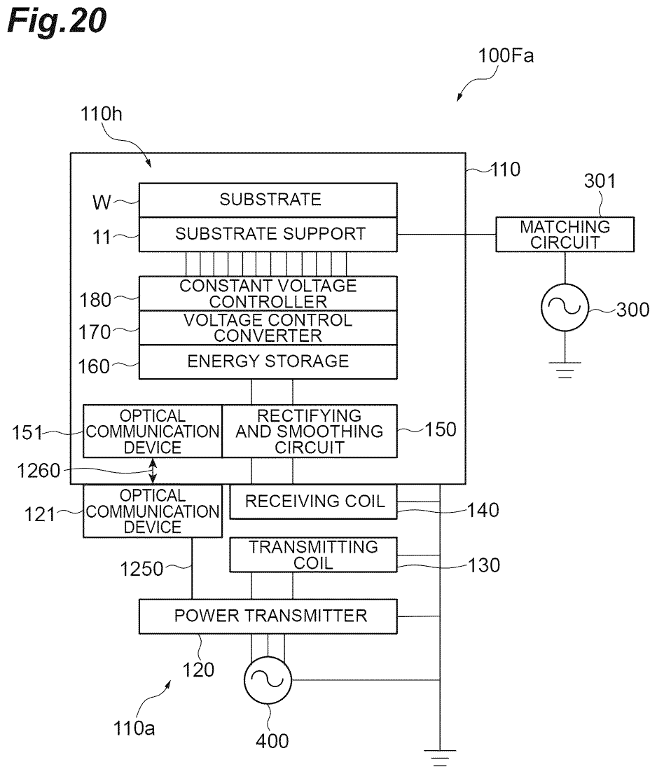

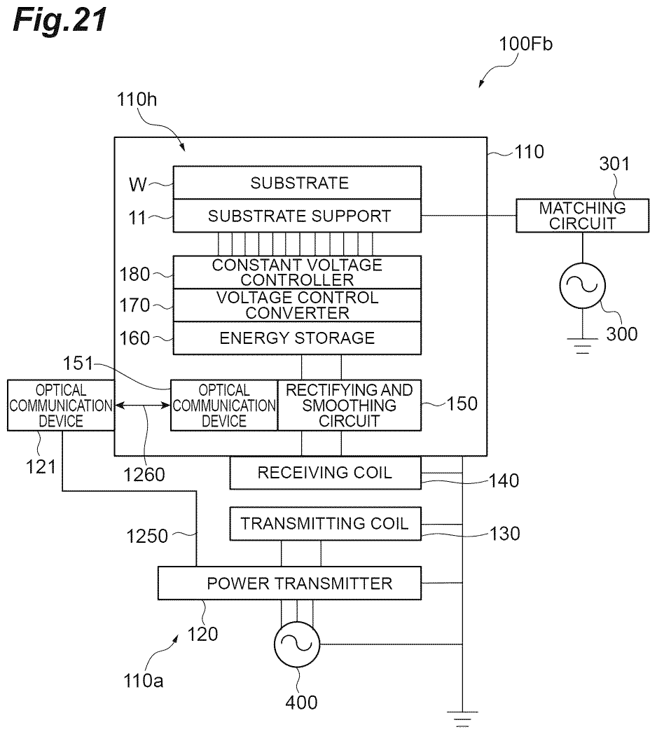

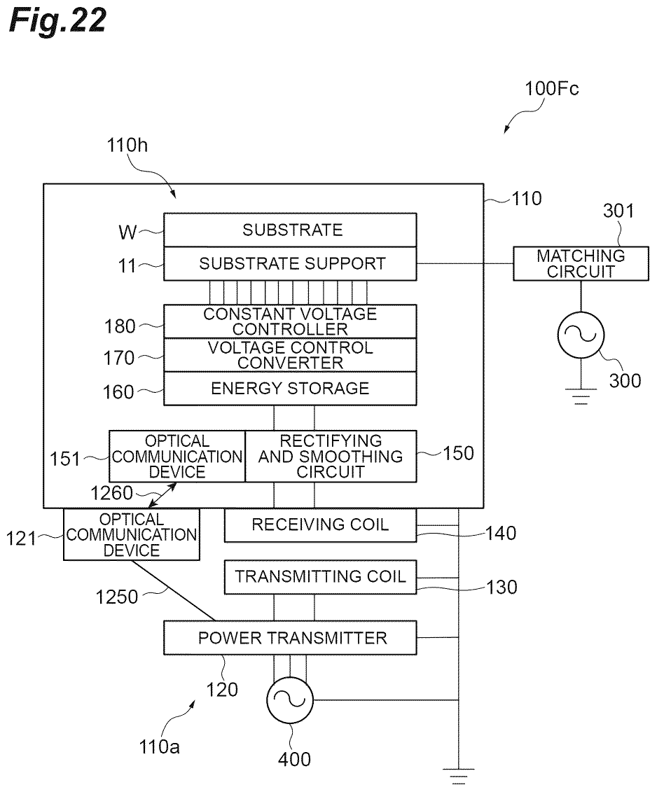

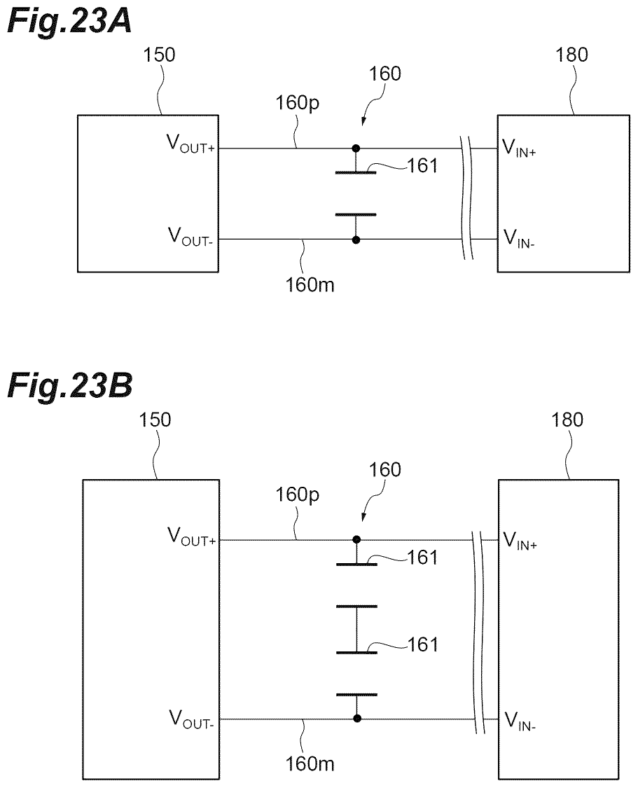

Reference is made to FIGS. 19 to 22. FIG. 19 is a diagram illustrating a communication device of a power transmitter and a communication device of a rectifying and smoothing circuit according to another example embodiment. Each of FIGS. 20 to 22 is a diagram schematically illustrating a plasma processing apparatus according to yet another example embodiment. As illustrated in FIGS. 19 to 22, the communication device 121 and the communication device 151 may be configured to transmit a signal (optical signal) such as the above-described instruction signal between each other via an optical fiber 1260, that is, by optical fiber communication. When the communication device 121 and the communication device 151 transmit signals between each other via the optical fiber 1260, the communication device 121 and the communication device 151 may be disposed at any position as long as the bending radius of the optical fiber 1260 is within an allowable range. In the examples illustrated in these figures as well, the RF filter 190 becomes unnecessary.

### Energy Storage

Reference is made to FIG. 23A and FIG. 23B. Each of FIG. 23A and FIG. 23B is a diagram illustrating an energy storage according to one example embodiment. As illustrated in FIG. 23A, the energy storage 160 includes a capacitor 161. The capacitor 161 is connected between a pair of power supply lines, namely a plus line 160p and a minus line 160m. The plus line 160p extends from the positive output (V_{OUT+}) of the rectifying and smoothing circuit 150 toward a load. The minus line 160m extends from the negative output (V_{OUT-}) of the rectifying and smoothing circuit 150 toward the load. The capacitor 161 may be a polarized capacitor. The capacitor 161 may be an electric double layer capacitor or a lithium-ion battery.

As illustrated in FIG. 23B, the energy storage 160 may include a plurality of capacitors 161. The plurality of capacitors 161 are connected in series between the plus line 160p and the minus line 160m. The plurality of capacitors 161 may have the same capacitance as each other or may have different capacitances from each other. Each of the plurality of capacitors 161 may be a polarized capacitor. Each of the plurality of capacitors 161 may be an electric double layer capacitor or a lithium-ion battery. The energy storage 160 needs to be used under a condition in which the sum of the input voltage applied thereto and the line-to-line potential difference due to normal mode noise is lower than the allowable input voltage. When the energy storage 160 includes a series connection of the plurality of capacitors 161, the allowable input voltage of the energy storage 160 becomes higher. Therefore, according to the example illustrated in FIG. 23B, the noise resistance of the energy storage 160 is improved.

### Voltage Control Converter

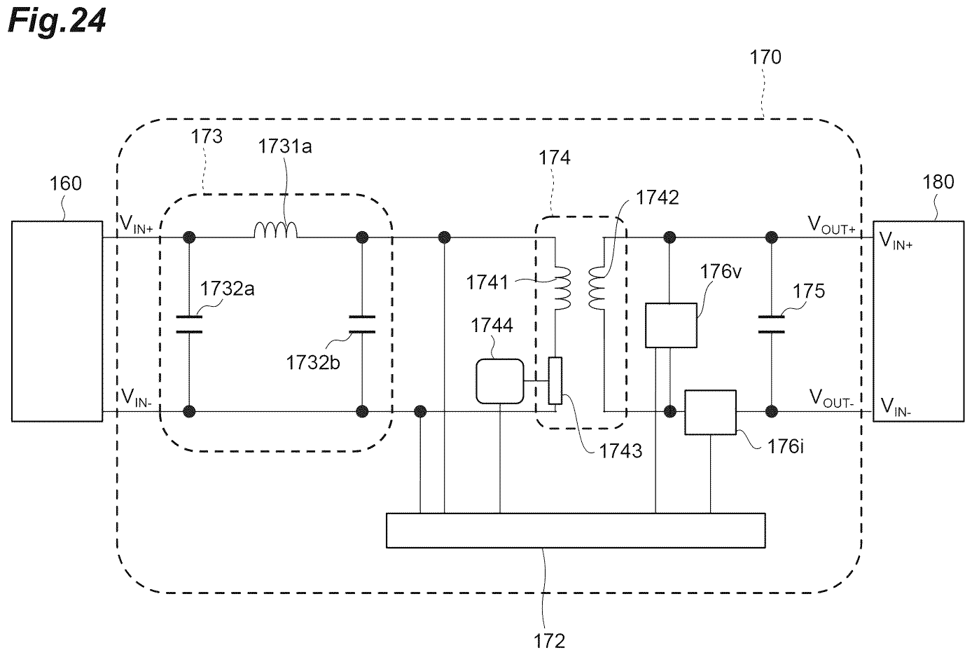

Reference is made to FIG. 24. FIG. 24 is a diagram illustrating a voltage control converter according to one example embodiment. The voltage control converter 170 is a DC-DC converter. The voltage control converter 170 is connected between the energy storage 160 and the constant voltage controller 180. The plus line 160p is connected to a positive input (V_{IN+}) of the voltage control converter 170. The minus line 160m is connected to a negative input (V_{IN-}) of the voltage control converter 170. A positive output (V_{OUT+}) of the voltage control converter 170 is connected to a positive input (V_{IN+}) of the constant voltage controller 180. A negative output (V_{OUT-}) of the voltage control converter 170 is connected to a negative input (V_{IN-}) of the constant voltage controller 180.

The voltage control converter 170 may include a controller 172, a low-pass filter 173, a transformer 174, and a capacitor 175. The low-pass filter 173 may include an inductor 1731a, a capacitor 1732a, and a capacitor 1732b. One end of the inductor 1731a is connected to the positive input (V_{IN+}) of the voltage control converter 170. The other end of the inductor 1731a is connected to one end of a primary coil of the transformer 174. One end of the capacitor 1732a is connected to one end of the inductor 1731a and the positive input (V_{IN+}) of the voltage control converter 170. The other end of the capacitor 1732a is connected to the negative input (V_{IN-}) of the voltage control converter 170. One end of the capacitor 1732b is connected to the other end of the inductor 1731a. The other end of the capacitor 1732b is connected to the negative input (V_{IN-}) of the voltage control converter 170.

The transformer 174 includes the primary coil 1741, a secondary coil 1742, and a switch 1743. The other end of the primary coil 1741 is connected to the negative input (V_{IN-}) of the voltage control converter 170 via the switch 1743. One end of the secondary coil 1742 is connected to one end of the capacitor 175 and the positive output (V_{OUT+}) of the voltage control converter 170. The other end of the secondary coil 1742 is connected to the other end of the capacitor 175 and the negative output (V_{OUT-}) of the voltage control converter 170.

A driver 1744 is connected to the switch 1743. The driver 1744 opens and closes the switch 1743. When the switch 1743 is closed, that is, when the other end of the primary coil 1741 and the negative input (V_{IN-}) are in a conductive state, the other end of the primary coil 1741 is connected to the negative input (V_{IN-}) of the voltage control converter 170, and DC power from the voltage control converter 170 is supplied to the constant voltage controller 180. On the other hand, when the switch 1743 is open, that is, when the other end of the primary coil 1741 and the negative input (V_{IN-}) are in a non-conductive state, the connection between the other end of the primary coil 1741 and the negative input (V_{IN-}) of the voltage control converter 170 is cut off, and the supply of DC power from the voltage control converter 170 to the constant voltage controller 180 is interrupted.

The voltage control converter 170 may further include a voltage detector 176v and a current detector 176i. The voltage detector 176v detects a voltage value between both ends of the secondary coil 1742 or a voltage value between the positive output and the negative output of the voltage control converter 170. The current detector 176i measures a current value between the other end of the secondary coil 1742 and the negative output of the voltage control converter 170. The voltage value detected by the voltage detector 176v and the current value detected by the current detector 176i are notified to the controller 172. The controller 172 may be the same as or different from at least one of the controller 122 and the controller 152.

The controller 172 controls the driver 1744 to cut off the supply of DC power from the voltage control converter 170 to the constant voltage controller 180 when the voltage value detected by the voltage detector 176v is equal to or greater than a threshold value. The voltage value between the positive output and the negative output of the voltage control converter 170 is the sum of the output voltage value of the voltage control converter 170 and the line-to-line potential difference due to normal mode noise. In this embodiment, damage to the load of the voltage control converter 170 due to overvoltage caused by the line-to-line potential difference due to normal mode noise can be suppressed.

### Constant Voltage Controller

Reference is made to FIGS. 25 and 26. FIGS. 25 and 26 are diagrams illustrating a constant voltage controller according to some example embodiments. The constant voltage controller 180 is connected between the energy storage 160 and at least one power consuming member 240, and is configured to control the application of a voltage (application of a DC voltage) to the at least one power consuming member 240 and the stopping thereof.

The constant voltage controller 180 includes a controller 182 and at least one switch 183. A positive input (V_{IN+}) of the constant voltage controller 180 is connected to the power consuming member 240 via the switch 183. A negative input (V_{IN-}) of the constant voltage controller 180 is connected to the power consuming member 240. The switch 183 is controlled by the controller 182. When the switch 183 is closed, a DC voltage from the constant voltage controller 180 is applied to the power consuming member 240. When the switch 183 is open, the application of the DC voltage from the constant voltage controller 180 to the power consuming member 240 is stopped. The controller 182 may be the same as or different from at least one of the controller 122, the controller 152, and the controller 172.

In the embodiment illustrated in FIGS. 25 and 26, the plasma processing apparatus includes a plurality of power consuming members 240. The constant voltage controller 180 includes a controller 182 and a plurality of switches 183. A positive input (V_{IN+}) of the constant voltage controller 180 is connected to the plurality of power consuming members 240 via the plurality of switches 183. A negative input (V_{IN-}) of the constant voltage controller 180 is connected to the plurality of power consuming members 240.

In the embodiment illustrated in FIGS. 25 and 26, the plurality of power consuming members 240 may include a plurality of heaters (resistance heating elements). The plurality of heaters may be provided in the substrate support 11. In the embodiment illustrated in FIG. 25, a plurality of resistors 260 are disposed in the vicinity of each of the plurality of heaters. Each of the plurality of resistors 260 has a resistance value that changes with temperature. Each of the plurality of resistors 260 is, for example, a thermistor. Each of the plurality of resistors 260 is connected in series with a reference resistor (not illustrated). The constant voltage controller 180 includes a plurality of measurement devices 184. Each of the plurality of measurement devices 184 applies a reference voltage to a series connection of the corresponding one of the plurality of resistors 260 and the reference resistor, and detects a voltage value across the resistor. Each of the plurality of measurement devices 184 notifies the controller 182 of the detected voltage value. The controller 182 identifies the temperature of the region in which the corresponding one of the plurality of heaters is disposed from the notified voltage value, and controls the application of the DC voltage to the corresponding heater so as to bring the temperature of the region close to a target temperature. Optical fiber thermometers may be disposed instead of the plurality of resistors 260. In this case, since wiring between the plurality of resistors 260 and the plurality of measurement devices 184 becomes unnecessary, the influence of radio frequency conducted noise on the power consuming member 240 can be eliminated.

In the embodiment illustrated in FIG. 26, the constant voltage controller 180 includes a voltage detector 185v and a plurality of current detectors 185i. The voltage detector 185v detects a voltage value applied to each of the plurality of heaters. Each of the plurality of current detectors 185i measures a value of current, that is, a current value, supplied to the corresponding one of the plurality of heaters. Each of the plurality of measurement devices 184 identifies the resistance value of the corresponding one of the plurality of heaters from the current value detected by the corresponding one of the plurality of current detectors 185i and the voltage value detected by the voltage detector 185v. The controller 182 identifies the temperature of each of a plurality of regions in which the plurality of heaters are respectively disposed from the detected resistance value of each of the plurality of heaters. The controller 182 controls the application of the DC voltage to each of the plurality of heaters so as to bring the temperature of each of the plurality of regions close to a target temperature.

### Receiving Coil in RF-Hot Space

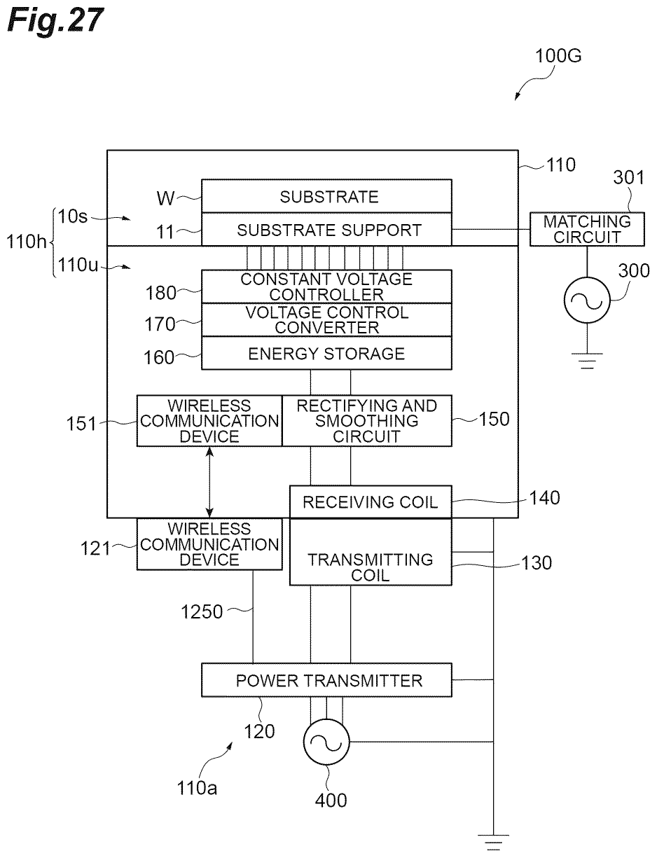

Reference is made to FIG. 27. FIG. 27 is a diagram schematically illustrating a plasma processing apparatus according to yet another example embodiment. Hereinafter, the plasma processing apparatus 100G illustrated in FIG. 27 will be described from the perspective of its differences from the plasma processing apparatus 100E illustrated in FIG. 7.

As described above, the space 110h includes the space inside the chamber 10 (plasma processing space 10s) and a space 110u that is a non-reduced-pressure space. As illustrated in FIG. 27, in the plasma processing apparatus 100G, the receiving coil 141 is disposed in the space 110u together with the rectifying and smoothing circuit 150 and the energy storage 160. On the other hand, the transmitting coil 131 is disposed in the space 110a.

In the plasma processing apparatus 100G, a circuit having high impedance with respect to the frequency of radio frequency power is provided by the stray capacitance of the space between the transmitting coil 131 and the receiving coil 141. Therefore, leakage of radio frequency power is reduced, and the utilization efficiency of radio frequency power is enhanced. Hence, if the process in the plasma processing apparatus 100G is etching, a high etching rate is obtained.

In one embodiment, the receiving coil 141 is disposed along the ground surface of the ground frame 110. In one embodiment, the receiving coil 141 is disposed in the space 110u at a distance equal to or greater than an insulation distance from the ground frame 110. In the plasma processing apparatus 100G, since the potential of the receiving coil 141 becomes approximate to the potential of radio frequency power in the space 110h or the space 110u, the influence of common mode noise, that is, conducted noise, is reduced. Therefore, as illustrated in FIG. 27, the receiving coil 141 and the rectifying and smoothing circuit 150 may be directly connected without passing through a filter such as the RF filter 200.

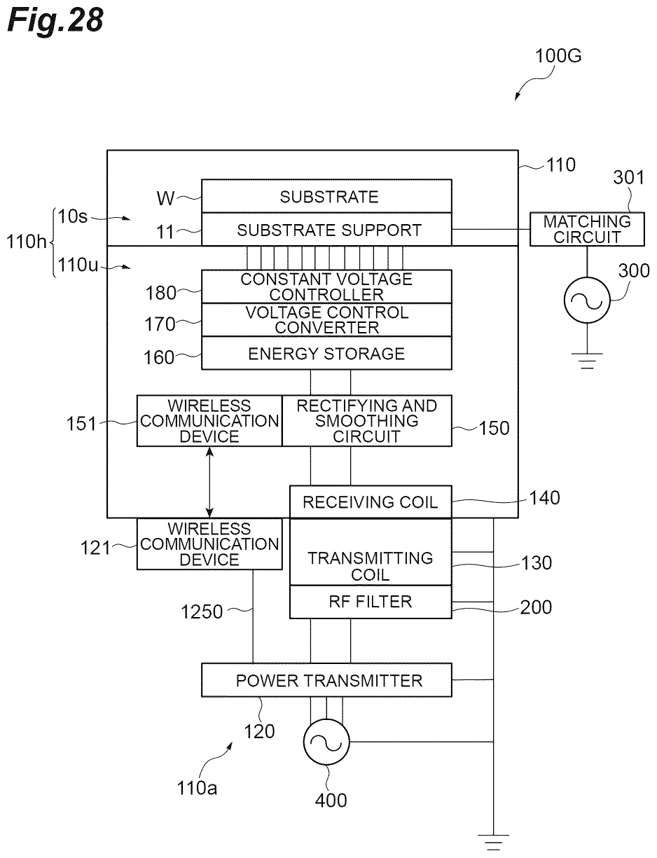

FIG. 28 is a diagram schematically illustrating a plasma processing apparatus according to yet another example embodiment. As illustrated in FIG. 28, in the plasma processing apparatus 100G, an RF filter 200 (radio frequency filter) may be connected between the transmitting coil 131 and the power transmitter 120 in order to cut radio frequency noise caused by radio frequency power. This further reduces conducted noise from the transmitting coil 131 to the power transmitter 120.

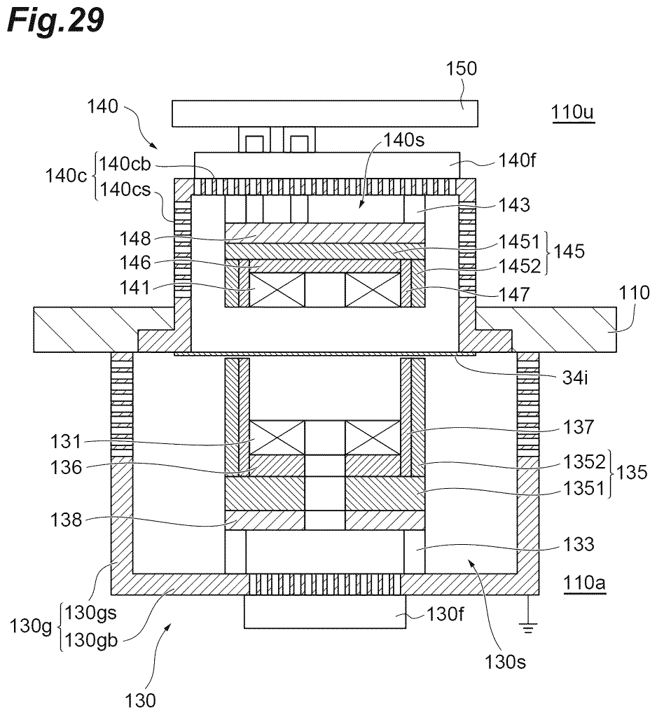

Hereinafter, some embodiments of the transmitting coil module 130 and the receiving coil module 140 that may be employed in the plasma processing apparatus 100G will be described with reference to FIGS. 29 to 35.

In each of the embodiments illustrated in FIGS. 29 to 35, the transmitting coil module 130 is disposed in the space 110a, and the receiving coil module 140 is disposed in the space 110u. The transmitting coil 131 and the receiving coil 141 face each other via an opening of the ground frame 110.

In the embodiment of FIG. 29, the transmitting coil module 130 has a metal housing 130g. The metal housing 130g is grounded and defines a shielded space 130s. The transmitting coil 131 is accommodated in the shielded space 130s. The metal housing 130g extends on the back side of the transmitting coil 131 relative to the receiving coil 141 and surrounds the outer periphery of the transmitting coil 131.

The metal housing 130g includes a back wall 130gb and a side wall 130gs. The back wall 130gb and the side wall 130gs define the shielded space 130s. The back wall 130gb has a substantially flat plate shape and extends on the back side of the transmitting coil 131 relative to the receiving coil 141. The side wall 130gs has a tubular shape such as a rectangular tubular shape or a cylindrical shape, and extends from the back wall 130gb toward the ground frame 110. The side wall 130gs surrounds the outer periphery of the transmitting coil 131. The tip of the side wall 130gs provides an opening. The tip of the side wall 130gs is fixed to the ground frame 110 such that its opening faces the opening of the ground frame 110. The opening at the tip of the side wall 130gs is closed by the ground frame 110 and an insulating plate 34i described below.

In the shielded space 130s and between the back wall 130gb and the transmitting coil 131, a spacer 133, a base plate 138, a back portion 1351 of the ferrite member 135, and a thermal conductive sheet 136 are disposed in this order.

The spacer 133 is fixed to the back wall 130gb and supports the base plate 138. The base plate 138 is, for example, a glass epoxy substrate. The base plate 138 supports the ferrite member 135. The ferrite member 135 includes a back portion 1351 extending on the back side of the transmitting coil 131. The back portion 1351 has a substantially flat plate shape. The thermal conductive sheet 136 is disposed between the back portion 1351 of the ferrite member 135 and the transmitting coil 131.

The ferrite member 135 may further include a side wall portion 1352. The side wall portion 1352 has a tubular shape such as a rectangular tubular shape or a cylindrical shape, and extends from the back portion 1351 toward the insulating plate 34i. The side wall portion 1352 surrounds the outer periphery of the transmitting coil 131 in the shielded space 130s. A thermal conductive sheet 137 may be disposed between the side wall portion 1352 and the transmitting coil 131 so as to surround the outer periphery of the transmitting coil 131. A single member may form the back portion 1351 and the side wall portion 1352, or separate members may respectively form the back portion 1351 and the side wall portion 1352.

The transmitting coil module 130 may further include a cooling mechanism 130f (first cooling mechanism or a first cooler). The cooling mechanism 130f may be a fan or a blower. The fan may be a supply fan or an exhaust fan. The cooling mechanism 130f is disposed outside the metal housing 130g along the metal housing 130g. In the example illustrated in FIG. 29, the cooling mechanism 130f is disposed along the back wall 130gb of the metal housing 130g. The back wall 130gb and the side wall 130gs of the metal housing 130g may provide a plurality of ventilation holes. The base plate 138, the back portion 1351 of the ferrite member 135, the thermal conductive sheet 136, and the transmitting coil 131 may also provide a gas flow path passing therethrough. The side wall portion 1352 of the ferrite member 135 and the thermal conductive sheet 137 may also provide a plurality of ventilation holes. With the cooling mechanism 130f, these ventilation holes, and the gas flow path, a flow of gas is formed from the exterior of the metal housing 130g (space 110a) through the shielded space 130s to the exterior of the metal housing 130g. Accordingly, the transmitting coil 131 and the ferrite member 135 are cooled.

In the embodiment of FIG. 29, the receiving coil module 140 has a housing 140c (insulating housing) formed of an insulating material. The housing 140c defines a space 140s. The receiving coil 141 is accommodated in the space 140s. The housing 140c extends on the back side of the receiving coil 141 relative to the transmitting coil 131 and surrounds the outer periphery of the receiving coil 141.

The housing 140c includes a back wall 140cb and a side wall 140cs. The back wall 140cb and the side wall 140cs define the space 140s. The back wall 140cb has a substantially flat plate shape and extends on the back side of the receiving coil 141 relative to the transmitting coil 131. The side wall 140cs has a tubular shape such as a rectangular tubular shape or a cylindrical shape, and extends from the back wall 140cb toward the ground frame 110. The side wall 140cs surrounds the outer periphery of the receiving coil 141. The tip of the side wall 140cs provides an opening. The tip of the side wall 140cs is fixed to the ground frame 110 such that its opening faces the opening at the tip of the side wall 130gs. The opening at the tip of the side wall 140cs is closed by the insulating plate 34i. The insulating plate 34i is formed of, for example, a resin such as PEEK (polyetheretherketone) or PPS (polyphenylene sulfide).

In the space 140s and between the back wall 140cb and the receiving coil 141, a spacer 143, a base plate 148, a back portion 1451 of the ferrite member 145, and a thermal conductive sheet 146 are disposed in this order.

The spacer 143 is fixed to the back wall 140cb and supports the base plate 148. The base plate 148 is, for example, a glass epoxy substrate. The base plate 148 supports the ferrite member 145. The ferrite member 145 includes a back portion 1451 extending on the back side of the receiving coil 141. The back portion 1451 has a substantially flat plate shape. The thermal conductive sheet 146 is disposed between the back portion 1451 of the ferrite member 145 and the receiving coil 141.

The ferrite member 145 may further include a side wall portion 1452. The side wall portion 1452 has a tubular shape such as a rectangular tubular shape or a cylindrical shape, and extends from the back portion 1451 toward the insulating plate 34i. The side wall portion 1452 surrounds the outer periphery of the receiving coil 141 in the space 140s. A thermal conductive sheet 147 may be disposed between the side wall portion 1452 and the receiving coil 141 so as to surround the outer periphery of the receiving coil 141. A single member may form the back portion 1451 and the side wall portion 1452, or separate members may respectively form the back portion 1451 and the side wall portion 1452.

The receiving coil module 140 may further include a cooling mechanism 140f (second cooling mechanism or a second cooler). The cooling mechanism 140f may be a fan or a blower. The fan may be a supply fan or an exhaust fan. The cooling mechanism 140f is disposed outside the housing 140c along the housing 140c. In the example illustrated in FIG. 29, the cooling mechanism 140f is disposed along the back wall 140cb of the housing 140c. The back wall 140cb and the side wall 140cs of the housing 140c may provide a plurality of ventilation holes. With the cooling mechanism 140f and these ventilation holes, a flow of gas is formed from the exterior of the housing 140c through the space 140s to the exterior of the housing 140c. Accordingly, the receiving coil 141 and the ferrite member 145 are cooled.

In the plasma processing apparatus 100G, the metal housing 130g suppresses leakage of radio frequency noise to the outside. In addition, the metal housing 130g and the housing 140c suppress intrusion of foreign matter into the interior of each of the transmitting coil module 130 and the receiving coil module 140.

In addition, the ferrite member 135 and the ferrite member 145 suppress leakage of magnetic flux. Therefore, high power transmission efficiency between the transmitting coil 131 and the receiving coil 141 can be obtained without increasing the number of turns of each of the transmitting coil 131 and the receiving coil 141. Hence, the resistance value of each of the transmitting coil 131 and the receiving coil 141 can be reduced. It is also possible to reduce the size of each of the transmitting coil 131 and the receiving coil 141.

In addition, since each of the ferrite member 135 and the ferrite member 145 has a side wall portion, each of the ferrite member 135 and the ferrite member 145 has a relatively large volume. Therefore, even if each of the ferrite member 135 and the ferrite member 145 generates heat due to conducted noise, the temperature rise thereof is small. In addition, since each of the ferrite member 135 and the ferrite member 145 has a relatively large volume, each of the ferrite member 135 and the ferrite member 145 has a relatively large inductance. The relatively large inductance of each of the ferrite member 135 and the ferrite member 145 and the small resistance value of each of the transmitting coil 131 and the receiving coil 141 result in a high Q value of each of the transmitting coil 131 and the receiving coil 141. Therefore, high power transmission efficiency between the transmitting coil 131 and the receiving coil 141 is ensured.

Each of the ferrite member 135 and the ferrite member 145 may be formed of a manganese-zinc ferrite, a nickel-zinc ferrite, or a nanocrystalline soft magnetic material. In this case, when the transmission frequency is 1 MHz or less, a high magnetic flux confinement effect at the transmission frequency is obtained due to high magnetic permeability, and it is possible to efficiently convert conducted noise into heat.

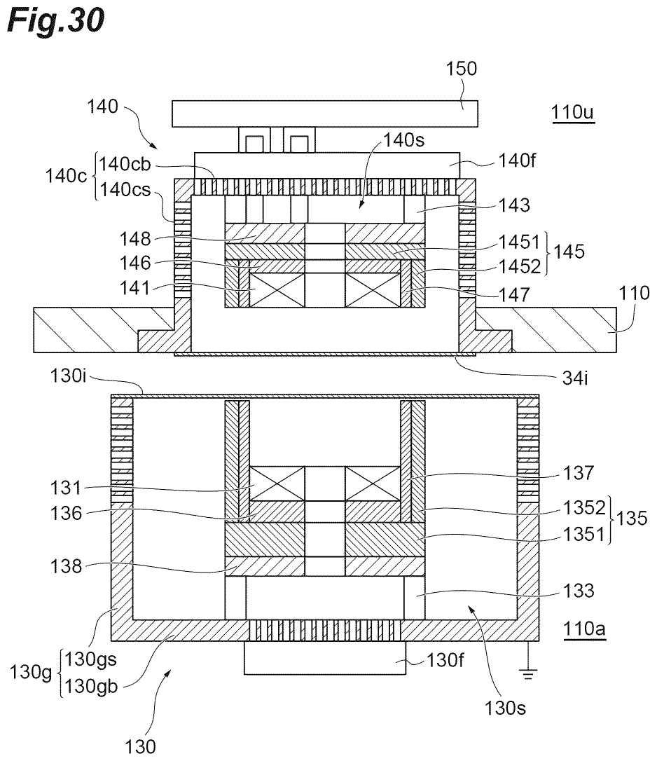

In the embodiment of FIG. 30, the transmitting coil module 130 is spaced apart from the ground frame 110 and the receiving coil module 140. In the transmitting coil module 130, the opening at the tip of the side wall 130gs of the metal housing 130g is closed by an insulating plate 130i. The insulating plate 130i is formed of a material similar to the material of the insulating plate 34i. The other configurations of the embodiment of FIG. 30 are the same as the corresponding configurations of the embodiment of FIG. 29.

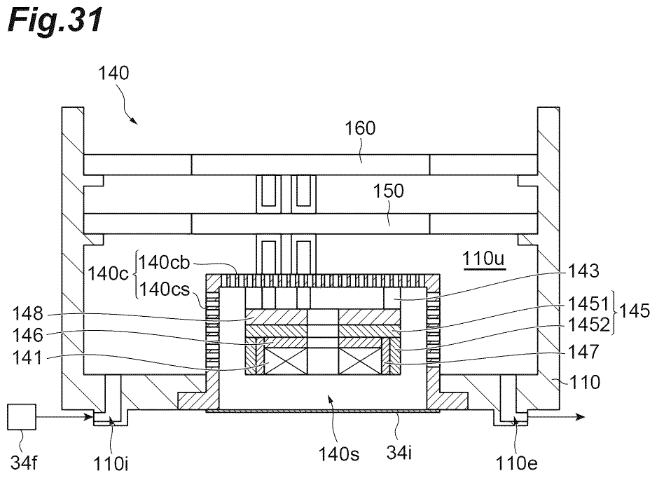

The embodiment of FIG. 31 is a modification of the receiving coil module 140 that may be employed in the embodiments of FIGS. 29 and 30. In the embodiment of FIG. 31, no cooling mechanism 140f is provided in the space 110u. In the embodiment of FIG. 31, a gas inlet 110i and a gas outlet 110e are formed in the ground frame 110. Each of the inlet 110i and the outlet 110e provides communication between the exterior of the ground frame 110 (space 110a) and the space 110u. In the embodiment of FIG. 31, a blower 34f provided outside the ground frame 110 forms a flow of gas from the exterior of the ground frame 110 through the inlet 110i, the space 110u, the space 140s, and the outlet 110e to the exterior of the ground frame 110. Accordingly, the rectifying and smoothing circuit 150 in addition to the receiving coil 141 and the ferrite member 145 is cooled.

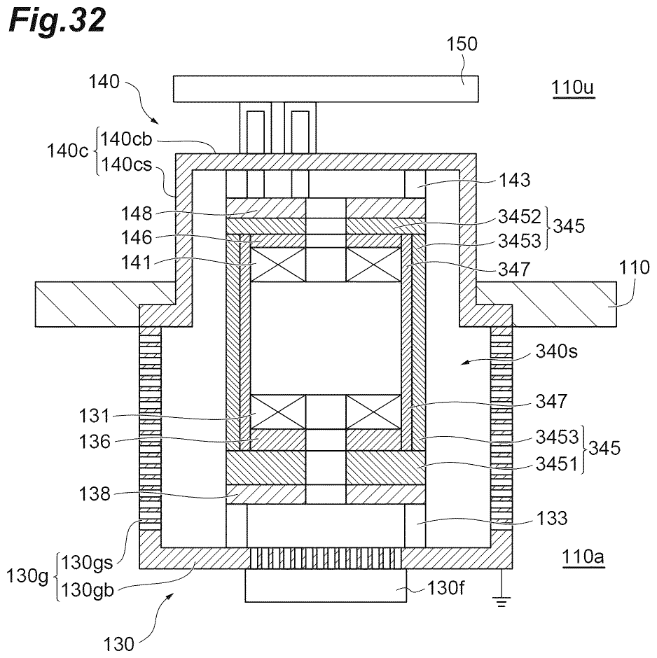

In the embodiment of FIG. 32, the tip of the side wall 130gs of the metal housing 130g is connected to the tip of the side wall 140cs of the housing 140c, and the transmitting coil module 130 and the receiving coil module 140 are integrated. In the embodiment of FIG. 32, the metal housing 130g and the housing 140c form a single closed space 340s.

In the embodiment of FIG. 32, a ferrite member 345 is used in place of the ferrite member 135 and the ferrite member 145. The ferrite member 345 is provided in the space 340s. The ferrite member 345 includes a back portion 3451, a back portion 3452, and a side wall portion 3453. The ferrite member 345 may be formed of a manganese-zinc ferrite, a nickel-zinc ferrite, or a nanocrystalline soft magnetic material. In this case, when the transmission frequency is 1 MHz or less, a high magnetic flux confinement effect at the transmission frequency is obtained due to high magnetic permeability, and it is possible to efficiently convert conducted noise into heat.

In the space 340s and between the back wall 130gb and the transmitting coil 131, the spacer 133, the base plate 138, the back portion 3451 of the ferrite member 345, and the thermal conductive sheet 136 are disposed in this order. In the space 340s and between the back wall 140cb and the receiving coil 141, the spacer 143, the base plate 148, the back portion 3452 of the ferrite member 345, and the thermal conductive sheet 146 are disposed in this order.

The back portion 3451 has a substantially flat plate shape and extends on the back side of the transmitting coil 131 in the space 340s. The back portion 3452 has a substantially flat plate shape and extends on the back side of the receiving coil 141 in the space 340s. The side wall portion 3453 has a tubular shape such as a rectangular tubular shape or a cylindrical shape, and extends from the back portion 3451 to the back portion 3452. The side wall portion 3453 surrounds the outer periphery of the transmitting coil 131 and the outer periphery of the receiving coil 141 in the space 340s. A thermal conductive sheet 347 may be disposed between each of the transmitting coil 131 and the receiving coil 141 and the side wall portion 3453 so as to surround the outer periphery of the transmitting coil 131 and the outer periphery of the receiving coil 141. A single member may form the back portion 3451, the back portion 3452, and the side wall portion 3453, or separate members may respectively form the back portion 3451, the back portion 3452, and the side wall portion 3453.

In the embodiment of FIG. 32, the cooling mechanism 140f is not used. In the embodiment of FIG. 32, a gas flow path is formed passing through the base plate 138, the back portion 3451 of the ferrite member 345, the thermal conductive sheet 136, the transmitting coil 131, the receiving coil 141, the thermal conductive sheet 146, the back portion 3452 of the ferrite member 345, and the base plate 148. In the embodiment of FIG. 32, a flow of gas is formed from the exterior of the metal housing 130g (space 110a) through the space 340s to the exterior of the metal housing 130g by the cooling mechanism 130f, the plurality of ventilation holes of the metal housing 130g, and the gas flow path. Accordingly, the transmitting coil 131, the receiving coil 141, and the ferrite member 345 are cooled.

The other configurations of the embodiment of FIG. 32 are similar to the corresponding configurations of the embodiment of FIG. 29.

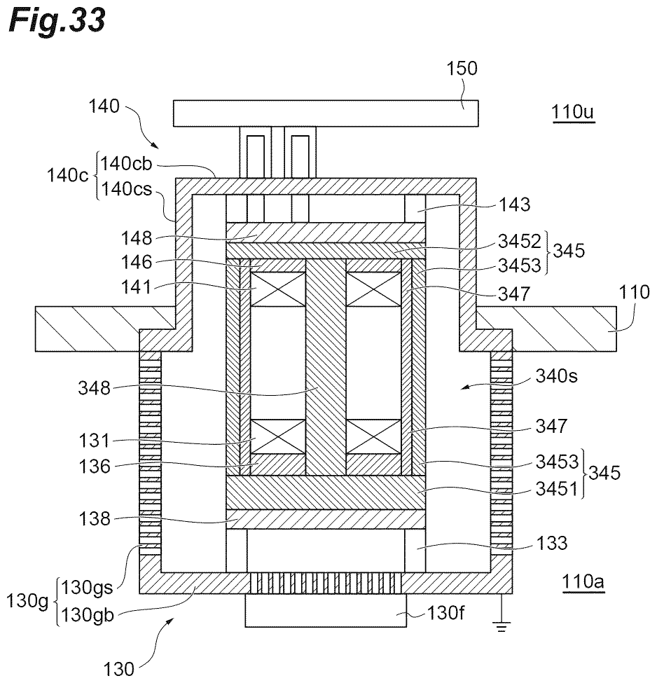

In the embodiment of FIG. 33, an inner ferrite member 348 is employed. The other configurations of the embodiment of FIG. 33 are similar to the corresponding configurations of the embodiment of FIG. 32. The inner ferrite member 348 has a columnar shape and extends from the back portion 3451 of the ferrite member 345 to the back portion 3452 of the ferrite member 345 through the inner region of the transmitting coil 131 and the inner region of the receiving coil 141. The inner ferrite member 348 may be separate from the ferrite member 345, or may be integrated with one or both of the back portion 3451 and the back portion 3452. With the inner ferrite member 348, the power transmission efficiency between the transmitting coil 131 and the receiving coil 141 is further improved.

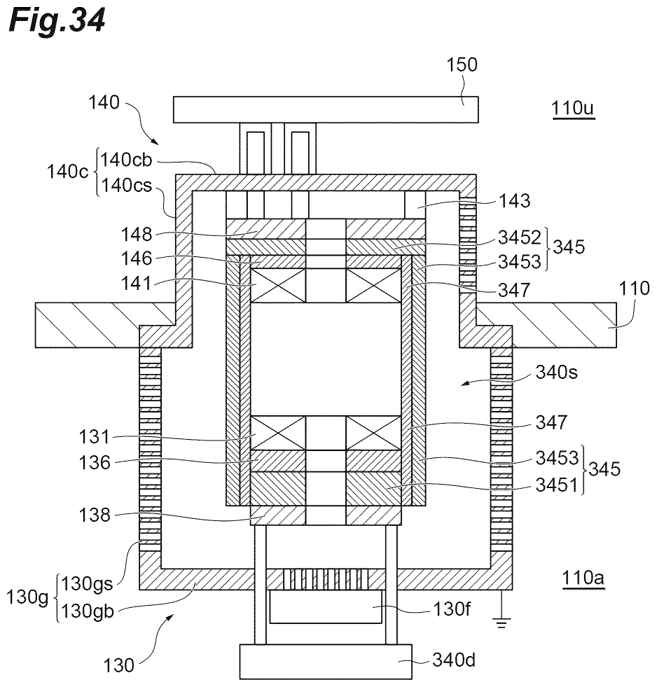

In the embodiment of FIG. 34, a transmitting coil assembly including the base plate 138, the back portion 3451, the thermal conductive sheet 136, and the transmitting coil 131 is movable inside the side wall portion 3453 of the ferrite member 345 in a direction approaching the receiving coil 141 and in the opposite direction. For this reason, in the embodiment of FIG. 34, a drive system 340d for moving the transmitting coil assembly is employed. The drive system 340d includes at least one actuator. The at least one actuator is composed of a hydraulic or pneumatic cylinder, a motor, a piezoelectric element, or the like. The drive system 340d may include a plurality of actuators. In the embodiment of FIG. 34, the side wall portion 3453 is configured to be capable of surrounding the outer periphery of the transmitting coil assembly. The drive system 340d is provided below the back wall 130gb in the space 110a and is coupled to the transmitting coil assembly (for example, the base plate 138) via one or more support rods. The other configurations of the embodiment of FIG. 34 are similar to the corresponding configurations of the embodiment of FIG. 32. In the embodiment of FIG. 34, the distance between the transmitting coil 131 and the receiving coil 141 is variable. Therefore, it is possible to change the impedance between the transmitting coil 131 and the receiving coil 141 with respect to the frequency of radio frequency power. It is also possible to change the level of power transmitted from the transmitting coil 131 to the receiving coil 141.

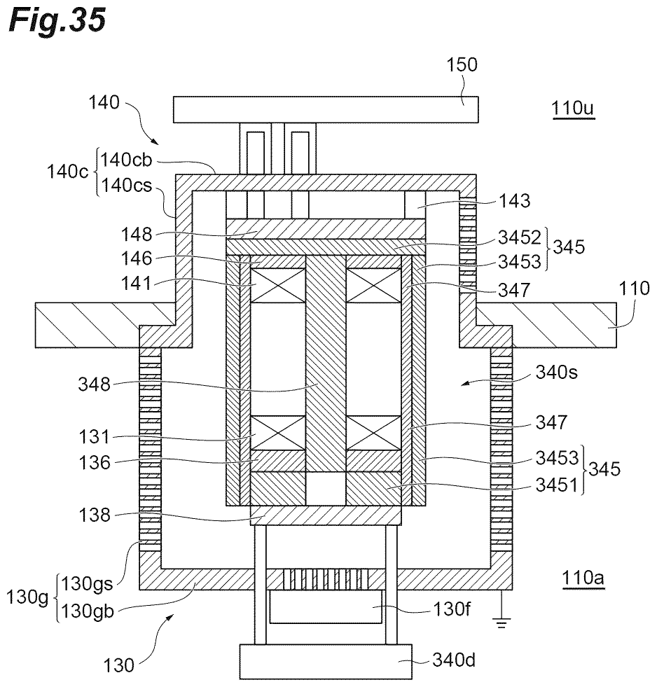

In the embodiment of FIG. 35, similarly to the embodiment of FIG. 33, an inner ferrite member 348 is employed. The inner ferrite member 348 has a columnar shape and extends from the back portion 3451 of the ferrite member 345 to the back portion 3452 of the ferrite member 345 through the inner region of the transmitting coil 131 and the inner region of the receiving coil 141. The other configurations of the embodiment of FIG. 35 are similar to the corresponding configurations of the embodiment of FIG. 34.

### Power Supply Without Using Energy storage

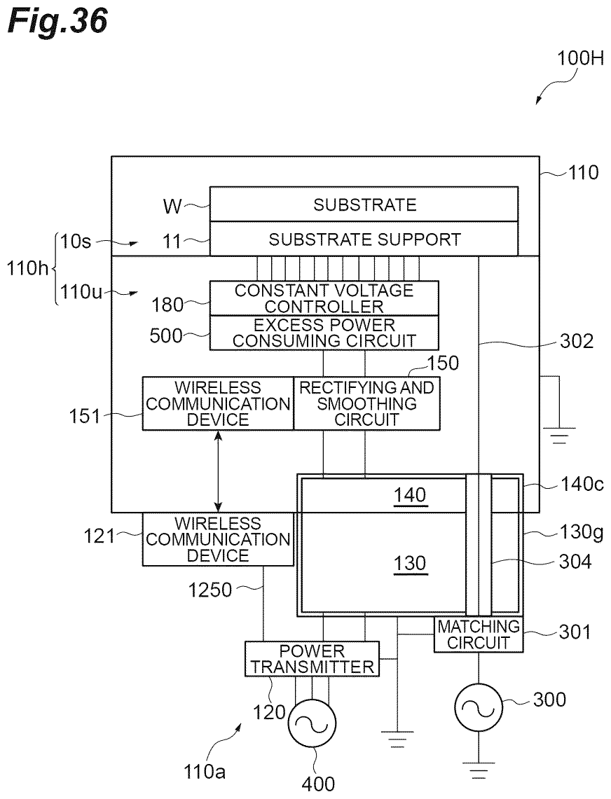

Reference is made to FIG. 36. FIG. 36 is a diagram schematically illustrating a plasma processing apparatus according to yet another example embodiment. Hereinafter, the plasma processing apparatus 100H illustrated in FIG. 36 will be described from the perspective of its differences from the plasma processing apparatus 100G illustrated in FIG. 27. As illustrated in FIG. 36, the plasma processing apparatus 100H does not include the RF filter 200, but may include the RF filter 200 similarly to the embodiment illustrated in FIG. 28.

As illustrated in FIG. 36, the plasma processing apparatus 100H does not include the energy storage 160. In the plasma processing apparatus 100H, the rectifying and smoothing circuit 150 is connected to the constant voltage controller 180 without passing through the energy storage 160 and the voltage control converter 170. That is, in the plasma processing apparatus 100H, the power generated by the rectifying and smoothing circuit 150 is supplied from the constant voltage controller 180 to at least one power consuming member 240 without passing through the energy storage 160 and the voltage control converter 170.

The constant voltage controller 180 controls the application of a voltage to each of the plurality of power consuming members 240 and the stopping thereof, as described above. Therefore, in the plasma processing apparatus 100H, the load that receives power from the rectifying and smoothing circuit 150 via the constant voltage controller 180 varies. That is, the load resistance value R_{L} varies. In order to supply power corresponding to the load resistance value R_{L} to the load, the controller 122 of the power transmitter 120 detects the input impedance Zᵢₙ of the power transmitter 120. This allows the controller 122 to detect the load variation, determine the required power level corresponding to the input impedance Zᵢₙ or the load resistance value R_{L}, and adjust the output power from the power transmitter 120.

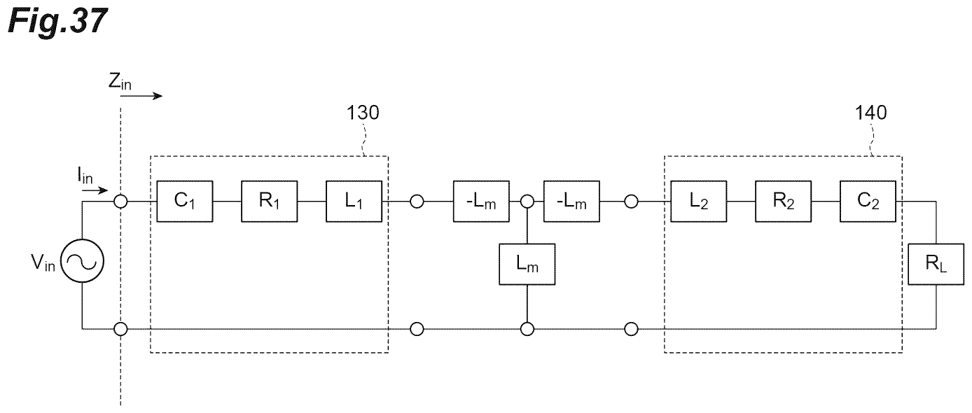

Here, reference is made to FIG. 37. FIG. 37 is a diagram illustrating an equivalent circuit of an example of a transmitting coil module and a receiving coil module in a state in which resonance occurs at the transmission frequency of the power transmitted from the power transmitter 120 and the phase difference between the input voltage Vᵢₙ and the input current Iᵢₙ is zero (power factor 100%). In one example, the equivalent circuit of the transmitting coil module and the receiving coil module includes, as illustrated in FIG. 37, the transmitting coil 131 having a self-inductance L₁, a load resistance of the transmitting coil 131 having a load resistance value R₁, a resonance capacitor of the transmitting coil module 130 having a capacitance C₁, three inductors disposed between the transmitting coil 131 and the receiving coil 141 and having a mutual inductance Lₘ, the receiving coil 141 having a self-inductance L₂, a load resistance of the receiving coil 141 having a load resistance value R₂, and a resonance capacitor of the receiving coil module 140 having a capacitance C₂. In the equivalent circuit of FIG. 37, Zᵢₙ is the input impedance of the power transmitter 120, Vᵢₙ is the input voltage from the power transmitter 120 to the transmitting coil module 130, and Iᵢₙ is the input current from the power transmitter 120 to the transmitting coil module 130. According to the equivalent circuit of FIG. 37, the input impedance Zᵢₙ is defined by the following equation (1).

Zᵢₙ=Vᵢₙ/Iᵢₙ=R₁+(2πfLₘ)²/(R₂+R_{L}) . . . (1)

In equation (1), f is the transmission frequency of the power transmitted from the power transmitter 120.

The controller 122 obtains the effective value of the input voltage Vᵢₙ from the voltage measured by the voltage detector 126v, and obtains the effective value of the input current Iᵢₙ from the current measured by the current detector 126i. The controller 122 can obtain the input impedance Zᵢₙ by equation (1) based on the input voltage Vᵢₙ and the input current Iᵢₙ. The controller 122 may further obtain the load resistance value R_{L} from the input impedance Zᵢₙ based on equation (1).

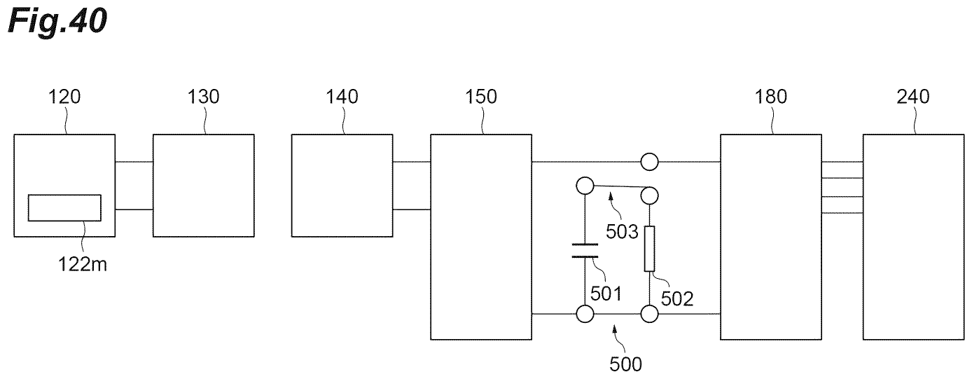

The controller 122 calculates the required power level corresponding to the parameter value that is the input impedance Zᵢₙ or the load resistance value R_{L} using at least one table. The controller 122 may identify, as parameters for specifying the required power level of the output power from the power transmitter 120, a peak value V_{P} of the output voltage Vₒᵤₜ, a duty ratio Duty of the output voltage Vₒᵤₜ, and an amplitude I_{A} of the output current Iₒᵤₜ. The at least one table is stored in a storage device 122m (see FIG. 40) such as a memory device connected to the controller 122. The storage device 122m may be a part of the power transmitter 120.

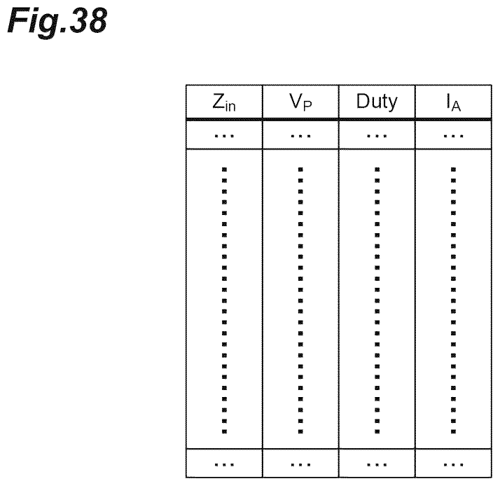

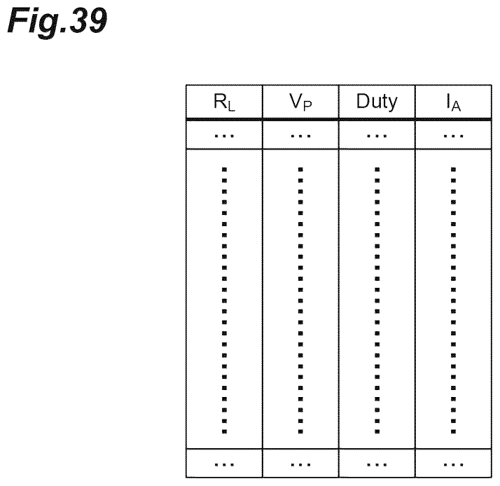

Each of FIGS. 38 and 39 is a diagram illustrating an example of the above-described at least one table. When the distance (gap length) between the transmitting coil 131 and the receiving coil 141 is fixed, the controller 122 can use a single table stored in the storage device 122m. The table stores, as illustrated in FIG. 38, the peak value V_{P}, the duty ratio Duty, and the amplitude I_{A} in association with the input impedance Zᵢₙ. The controller 122 can identify the required power level corresponding to the input impedance Zᵢₙ, that is, the peak value V_{P}, the duty ratio Duty, and the amplitude I_{A}, by referring to the table illustrated in FIG. 38 using the input impedance Zᵢₙ as a key. The controller 122 controls each component of the power transmitter 120 so as to output the output power having the peak value V_{P} and the duty ratio Duty of the output voltage Vₒᵤₜ, and the amplitude I_{A} of the output current Iₒᵤₜ.

Alternatively, when the transmission frequency f, the mutual inductance Lm, the load resistance value R₁, and the load resistance value R₂ are stored in the storage device 122m, the controller 122 may obtain the load resistance value R_{L} by equation (1) based on the transmission frequency f, the mutual inductance Lm, the load resistance value R₁, the load resistance value R₂, and the input impedance Zᵢₙ. The storage device 122m may store 2πf instead of the transmission frequency f. The storage device 122m may also store the self-inductance L₁ of the transmitting coil 131, the self-inductance L₂ of the receiving coil 141, and the coupling coefficient k between the transmitting coil 131 and the receiving coil 141 instead of the mutual inductance Lₘ, and the controller 122 may calculate the mutual inductance Lₘ from the self-inductance L₁, the self-inductance L₂, and the coupling coefficient k. Alternatively, the storage device 122m may store 2πfLₘ or (2πfLₘ)² instead of the transmission frequency f and the mutual inductance Lₘ.

The table also stores, as illustrated in FIG. 39, the peak value V_{P}, the duty ratio Duty, and the amplitude I_{A} in association with the load resistance value R_{L}. The controller 122 can identify the required power level corresponding to the load resistance value R_{L}, that is, the peak value V_{P}, the duty ratio Duty, and the amplitude I_{A}, by referring to the table illustrated in FIG. 39 using the load resistance value R_{L} as a key. The controller 122 controls each component of the power transmitter 120 so as to output the output power having the peak value V_{P} and the duty ratio Duty of the output voltage Vₒᵤₜ, and the amplitude I_{A} of the output current Iₒᵤₜ.

When the distance (gap length) between the transmitting coil 131 and the receiving coil 141 is variable as described below, the storage device 122m stores a plurality of tables similar to the table illustrated in FIG. 38 or FIG. 39. The plurality of tables are prepared for each of a plurality of settable distances between the transmitting coil 131 and the receiving coil 141. The controller 122 can select the table to be used according to the current distance between the transmitting coil 131 and the receiving coil 141.

As described above, according to the plasma processing apparatus 100H, it is possible to supply power by electromagnetic induction coupling without using an energy storage in accordance with the load resistance value R_{L} of the power consuming member 240. That is, according to the plasma processing apparatus 100H, it is possible to supply power corresponding to a variation in the load resistance value R_{L} of the power consuming member 240 (hereinafter sometimes referred to as “load variation”) by electromagnetic induction coupling without using an energy storage.

Since the controller 122 can identify the variation in the load resistance value R_{L} by obtaining the input impedance Zᵢₙ, it is not necessary to issue a power change instruction from the constant voltage controller 180 via the communication device 151 and the communication device 121. However, since the load variation is caused by the constant voltage controller 180, a power change instruction may be notified in advance to the controller 122 from the constant voltage controller 180 via the communication device 151 and the communication device 121 before the load variation occurs. This load variation may also be performed by the constant voltage controller 180 at a timing synchronized with the output power having the transmission frequency f output from the receiving coil module 140. Specifically, a synchronization signal synchronized with the output power having the transmission frequency f from the receiving coil module 140 may be generated by the rectifying and smoothing circuit 150, and the constant voltage controller 180 may cause the load variation at a timing synchronized with the output power using this synchronization signal. The load variation may be set so as not to be performed simultaneously with a change in the distance between the transmitting coil 131 and the receiving coil 141.

Hereinafter, reference is made to FIG. 40 together with FIG. 36. FIG. 40 is a diagram schematically illustrating a plasma processing apparatus according to yet another example embodiment. As illustrated in FIGS. 36 and 40, the plasma processing apparatus 100H may include an excess power consuming circuit 500. The excess power consuming circuit 500 may include a line capacitor 501, an excess power consuming load 502, and a switching element 503.

The line capacitor 501 can be connected via the switching element 503 between a pair of power supply lines connecting the rectifying and smoothing circuit 150 and the constant voltage controller 180 to each other, namely a plus line and a minus line. Specifically, one end of the line capacitor 501 is connected to the switching element 503, and the other end of the line capacitor 501 is connected to the minus line.

The excess power consuming load 502 is a load for consuming the power stored in the line capacitor 501. The excess power consuming load 502 can consume power by converting power into heat. The excess power consuming load 502 may be provided with a cooling mechanism such as a fan for cooling thereof. The excess power consuming load 502 can be selectively connected to the line capacitor 501 via the switching element 503. One end of the excess power consuming load 502 is connected to the switching element 503, and the other end of the excess power consuming load 502 is connected to the minus line.

When the state of the switching element 503 is ON, the switching element 503 cuts off the connection between the line capacitor 501 and the excess power consuming load 502 and connects one end of the line capacitor 501 to the plus line. When the state of the switching element 503 is OFF, the switching element 503 cuts off the connection between one end of the line capacitor 501 and the plus line and connects one end of the line capacitor 501 to one end of the excess power consuming load 502. A semiconductor switching element may be used as the switching element 503 from the viewpoint of its high-speed response.

The state of the switching element 503 can be controlled by, for example, the controller 182 of the constant voltage controller 180. The controller 182 of the constant voltage controller 180 sets the state of the switching element 503 to ON when causing a load variation, particularly when decreasing the load resistance value R_{L}. The controller 182 sets the state of the switching element 503 to OFF after the level of power transmitted from the power transmitter 120 has been changed to the power level corresponding to the load resistance value R_{L}.

With such an excess power consuming circuit 500, power is temporarily stored in the line capacitor 501 during the period from when the load variation occurs until the power level is changed. Therefore, an inflow of a large current to the constant voltage controller 180 and the power consuming member 240 is suppressed, and damage to the constant voltage controller 180 and the power consuming member 240 can be suppressed. Further, with the excess power consuming circuit 500, the power stored in the line capacitor 501 is consumed in the excess power consuming load 502.

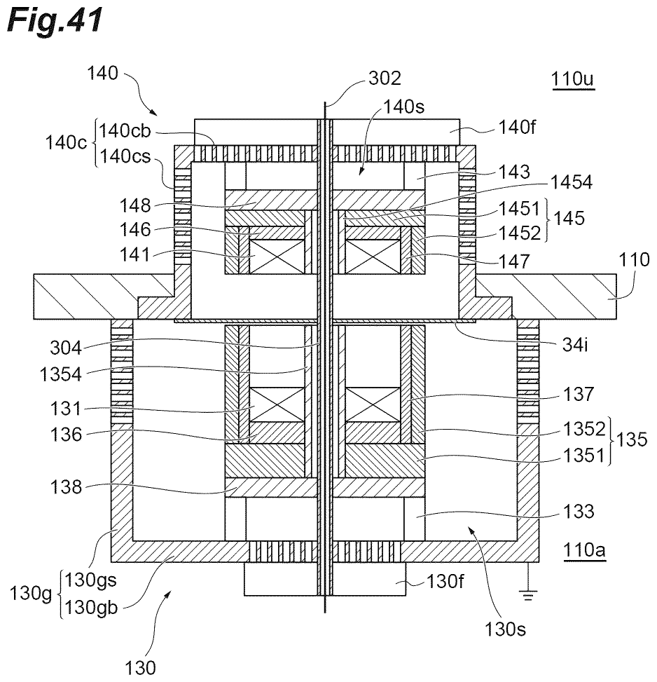

Hereinafter, reference is made to FIG. 41. FIG. 41 is a diagram illustrating a transmitting coil module and a receiving coil module that may be employed in a plasma processing apparatus according to yet another example embodiment. The transmitting coil module 130 and the receiving coil module 140 illustrated in FIG. 41 may be employed in the plasma processing apparatus 100H. The transmitting coil module 130 and the receiving coil module 140 illustrated in FIG. 41 may also be employed in plasma processing apparatuses according to various example embodiments other than the plasma processing apparatus 100H. Hereinafter, the configuration illustrated in FIG. 41 will be described from the perspective of its differences from the configuration illustrated in FIG. 29.

As illustrated in FIG. 41, the ferrite member 135 may further include an inner ferrite portion 1354. The inner ferrite portion 1354 has a substantially tubular shape similar to the side wall portion 1352 that is an outer ferrite portion, and is disposed inside the side wall portion 1352 substantially coaxially with the side wall portion 1352. The inner ferrite portion 1354 extends through the inner side of the transmitting coil 131 toward the insulating plate 34i.

The ferrite member 145 may also further include an inner ferrite portion 1454. The inner ferrite portion 1454 has a substantially tubular shape similar to the side wall portion 1452 that is an outer ferrite portion, and is disposed inside the side wall portion 1452 substantially coaxially with the side wall portion 1452. The inner ferrite portion 1454 extends through the inner side of the receiving coil 141 toward the insulating plate 34i.

The radio frequency power supply 300 may be electrically coupled to the substrate support 11 via a radio frequency power supply line 302, similarly to the various example embodiments described above. The radio frequency power supply line 302 extends from the substrate support 11 through the space 110u to the space 110a and is connected to the matching circuit 301, and is electrically coupled to the radio frequency power supply 300 via the matching circuit 301. In the space 110a, the radio frequency power supply line 302 passes through a ground pipe 304 and is surrounded by the ground pipe 304. The ground pipe 304 is a tubular conductor and is electrically grounded. The ground pipe 304 may be electrically connected to the ground frame 110. The ground pipe 304 may extend from the ground frame 110 to the matching circuit 301.

In the plasma processing apparatus 100H, the ground pipe 304 extends through the inner side of the transmitting coil 131 and the inner side of the receiving coil 141. The ground pipe 304 may pass through the inner ferrite portions 1354 and 1454 at a distance from the inner ferrite portions 1354 and 1454. The ground pipe 304 and each of the inner ferrite portions 1354 and 1454 may be separated from each other by an insulation distance or more.

In the plasma processing apparatus 100H, the radio frequency power supply line 302 and the ground pipe 304 extend through the inner side of the transmitting coil 131 and the inner side of the receiving coil 141 in the space 110a. Therefore, it is possible to reduce the space for the radio frequency power supply line 302 outside the chamber 10. Hence, according to the plasma processing apparatus 100H, a high degree of freedom in the layout of other components in the space 110a is obtained. In addition, since the space available in the space 110a is large, it is possible to increase the size of each of the transmitting coil 131 and the receiving coil 141. As a result, transmission of large power becomes possible.

In addition, the ferrite members 135 and 145 suppress leakage of magnetic flux. Therefore, high power transmission efficiency between the transmitting coil 131 and the receiving coil 141 is obtained.

In the plasma processing apparatus 100H, the receiving coil module 140 may have the configuration of FIG. 31. In this case as well, similarly to the configuration of FIG. 41, the inner ferrite portion 1454 and the ground pipe 304 may extend through the inner side of the receiving coil 141.

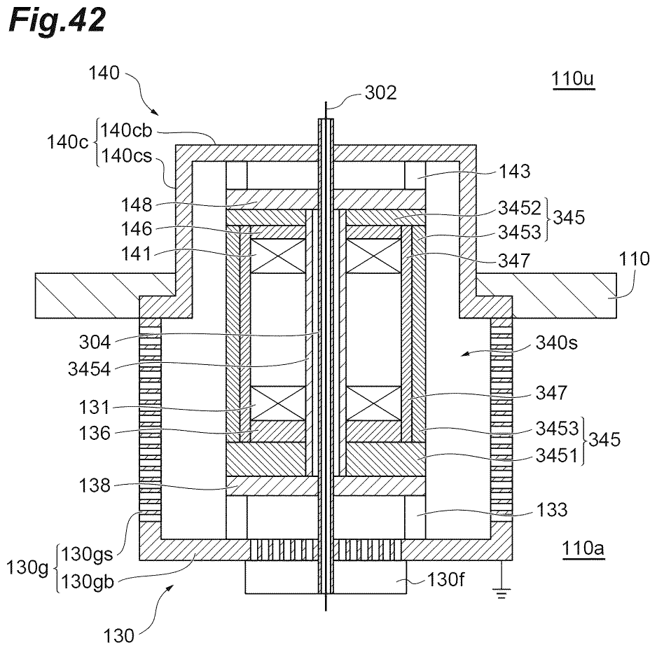

Hereinafter, reference is made to FIG. 42. FIG. 42 is a diagram illustrating a transmitting coil module and a receiving coil module that may be employed in a plasma processing apparatus according to yet another example embodiment. The transmitting coil module 130 and the receiving coil module 140 illustrated in FIG. 42 may be employed in the plasma processing apparatus 100H. The transmitting coil module 130 and the receiving coil module 140 illustrated in FIG. 42 may also be employed in plasma processing apparatuses according to various example embodiments other than the plasma processing apparatus 100H. Hereinafter, the configuration illustrated in FIG. 42 will be described from the perspective of its differences from the configuration illustrated in FIG. 32.

As illustrated in FIG. 42, the ferrite member 345 may further include an inner ferrite portion 3454. The inner ferrite portion 3454 has a substantially tubular shape similar to the side wall portion 3453 that is an outer ferrite portion, and is disposed inside the side wall portion 3453 substantially coaxially with the side wall portion 3453. The inner ferrite portion 3454 extends through the inner side of the transmitting coil 131 and the inner side of the receiving coil 141.

In the configuration illustrated in FIG. 42 as well, similarly to the configuration illustrated in FIG. 41, the plasma processing apparatus 100H includes the radio frequency power supply line 302 and the ground pipe 304, and the radio frequency power supply 300 is electrically coupled to the substrate support 11 via the radio frequency power supply line 302 extending through the ground pipe 304. In the configuration illustrated in FIG. 42 as well, similarly to the configuration illustrated in FIG. 41, the ground pipe 304 extends through the inner side of the transmitting coil 131 and the inner side of the receiving coil 141. The ground pipe 304 may pass through the inner ferrite portion 3454 at a distance from the inner ferrite portion 3454. The ground pipe 304 and the inner ferrite portion 3454 may be separated from each other by an insulation distance or more.

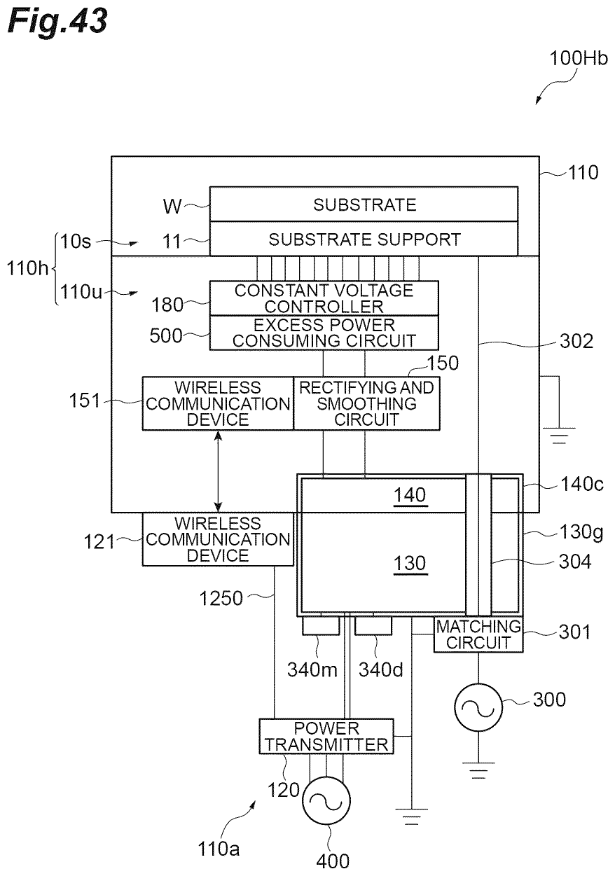

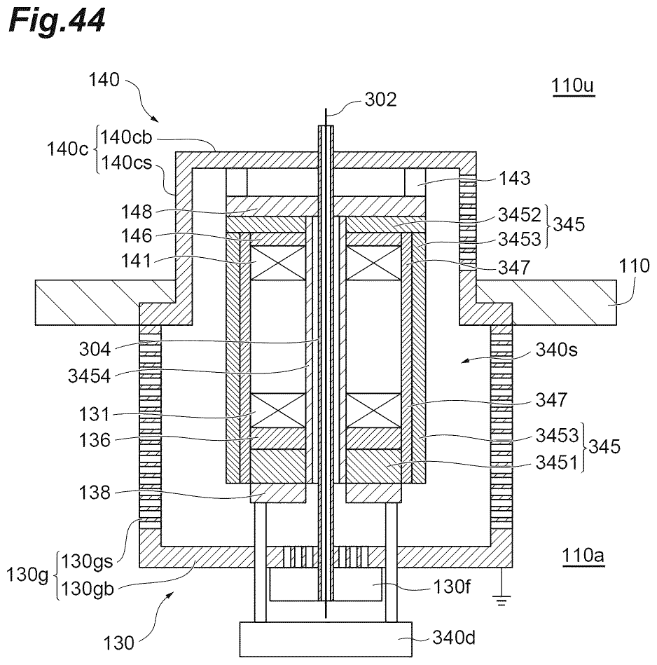

Reference is made to FIGS. 43 and 44. FIG. 43 is a diagram schematically illustrating a plasma processing apparatus according to yet another example embodiment. FIG. 44 is a diagram illustrating a transmitting coil module and a receiving coil module that may be employed in a plasma processing apparatus according to yet another example embodiment. The plasma processing apparatus 100Hb illustrated in FIG. 43 has the configuration of the transmitting coil module 130 and the receiving coil module 140 illustrated in FIG. 44. The transmitting coil module 130 and the receiving coil module 140 illustrated in FIG. 44 may also be employed in plasma processing apparatuses according to various example embodiments other than the plasma processing apparatus 100Hb. Hereinafter, the plasma processing apparatus 100Hb illustrated in FIG. 43 will be described from the perspective of its differences from the plasma processing apparatus 100H illustrated in FIG. 36. The configuration illustrated in FIG. 44 will also be described from the perspective of its differences from the configuration illustrated in FIG. 34.

The plasma processing apparatus 100Hb can change the distance (gap length) between the transmitting coil 131 and the receiving coil 141, similarly to the configuration illustrated in FIG. 34. The plasma processing apparatus 100Hb further includes a drive system 340d and a sensor 340m. The drive system 340d is configured to move the transmitting coil 131 to change the distance between the transmitting coil 131 and the receiving coil 141, that is, the length of the gap between the transmitting coil 131 and the receiving coil 141. The drive system 340d includes at least one actuator. The at least one actuator includes a hydraulic or pneumatic cylinder, a motor, a piezoelectric element, or the like. The drive system 340d may include a plurality of actuators. The drive system 340d may detect the parallelism between the transmitting coil 131 and the receiving coil 141 using the sensor 340m and control the at least one actuator so as to keep the transmitting coil 131 and the receiving coil 141 parallel to each other according to the detection result of the sensor 340m.

As illustrated in FIG. 44, the plasma processing apparatus 100Hb further includes the radio frequency power supply line 302 and the ground pipe 304. In the configuration illustrated in FIG. 44 as well, similarly to the configuration illustrated in FIG. 42, the radio frequency power supply 300 is electrically coupled to the substrate support 11 via the radio frequency power supply line 302 extending through the ground pipe 304. In the configuration illustrated in FIG. 44 as well, similarly to the configuration illustrated in FIG. 42, the ground pipe 304 extends through the inner side of the transmitting coil 131 and the inner side of the receiving coil 141. The ground pipe 304 may pass through the inner ferrite portion 3454 spaced apart from the inner ferrite portion 3454. The ground pipe 304 and the inner ferrite portion 3454 may be separated from each other by an insulation distance or more.

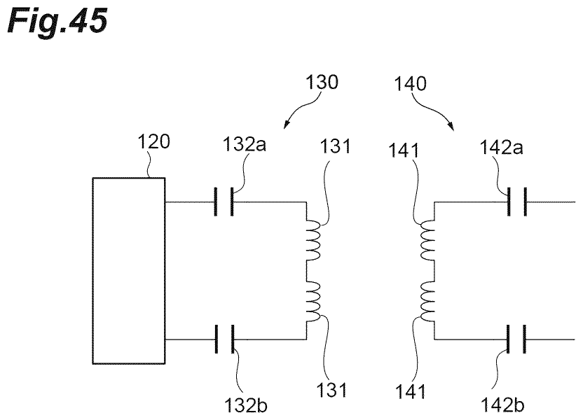

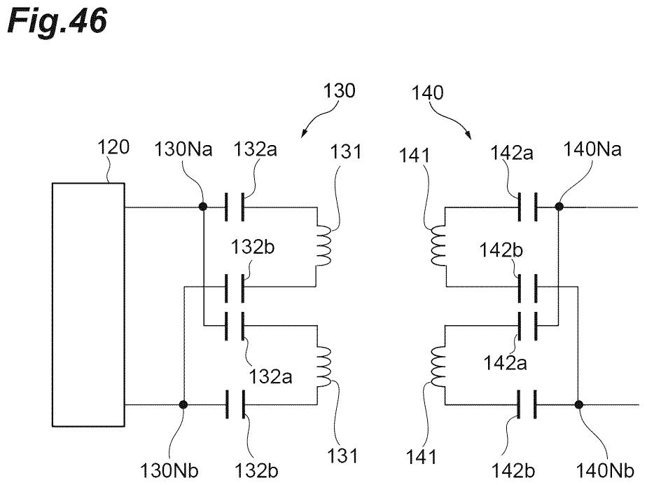

Hereinafter, reference is made to FIGS. 45 and 46. FIGS. 45 and 46 are diagrams illustrating a transmitting coil module and a receiving coil module in a plasma processing apparatus according to yet another example embodiment.

As illustrated in FIG. 45, in plasma processing apparatuses according to various example embodiments, the transmitting coil module 130 may include two or more transmitting coils 131 connected in series. The receiving coil module 140 may also include two or more receiving coils 141 connected in series. The two or more transmitting coils 131 are electromagnetically coupled to the two or more receiving coils 141.

As illustrated in FIG. 46, in plasma processing apparatuses according to various example embodiments, the transmitting coil module 130 may include two transmitting coils 131 connected in parallel. The receiving coil module 140 may also include two receiving coils 141 connected in parallel. A first transmitting coil of the two transmitting coils 131 is electromagnetically coupled to a first receiving coil of the two receiving coils 141. A second transmitting coil of the two transmitting coils 131 is electromagnetically coupled to a second receiving coil of the two receiving coils 141.

One end of the first transmitting coil is connected to the power transmitter 120 via one of the two resonance capacitors 132a and a node 130Na. The other end of the first transmitting coil is connected to the power transmitter 120 via one of the two resonance capacitors 132b and a node 130Nb. One end of the second transmitting coil is connected to the power transmitter 120 via the other of the two resonance capacitors 132a and the node 130Na. The other end of the second transmitting coil is connected to the power transmitter 120 via the other of the two resonance capacitors 132b and the node 130Nb.

One end of the first receiving coil is connected to the rectifying and smoothing circuit 150 via one of the two resonance capacitors 142a and a node 140Na. The other end of the first receiving coil is connected to the rectifying and smoothing circuit 150 via one of the two resonance capacitors 142b and a node 140Nb. One end of the second receiving coil is connected to the rectifying and smoothing circuit 150 via the other of the two resonance capacitors 142a and the node 140Na. The other end of the second receiving coil is connected to the rectifying and smoothing circuit 150 via the other of the two resonance capacitors 142b and the node 140Nb.

A single resonance capacitor 132a may be connected between the node 130Na and the power transmitter 120. A single resonance capacitor 132b may also be connected between the node 130Nb and the power transmitter 120. In this case, one end of the first transmitting coil is connected to the power transmitter 120 via the node 130Na and the single resonance capacitor 132a, and the other end of the first transmitting coil is connected to the power transmitter 120 via the node 130Nb and the single resonance capacitor 132b. One end of the second transmitting coil is also connected to the power transmitter 120 via the node 130Na and the single resonance capacitor 132a, and the other end of the second transmitting coil is connected to the power transmitter 120 via the node 130Nb and the single resonance capacitor 132b.

A single resonance capacitor 142a may also be connected between the node 140Na and the rectifying and smoothing circuit 150. A single resonance capacitor 142b may also be connected between the node 140Nb and the rectifying and smoothing circuit 150. In this case, one end of the first receiving coil is connected to the rectifying and smoothing circuit 150 via the node 140Na and the single resonance capacitor 142a, and the other end of the first receiving coil is connected to the rectifying and smoothing circuit 150 via the node 140Nb and the single resonance capacitor 142b. One end of the second receiving coil is also connected to the rectifying and smoothing circuit 150 via the node 140Na and the single resonance capacitor 142a, and the other end of the second receiving coil is connected to the rectifying and smoothing circuit 150 via the node 140Nb and the single resonance capacitor 142b.

### Plasma Processing Apparatus Including Immittance Converter

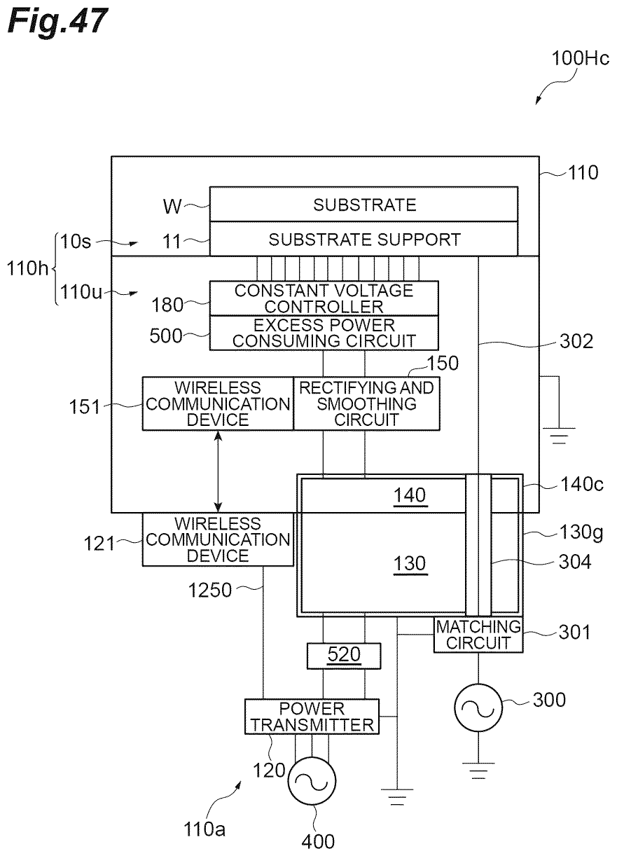

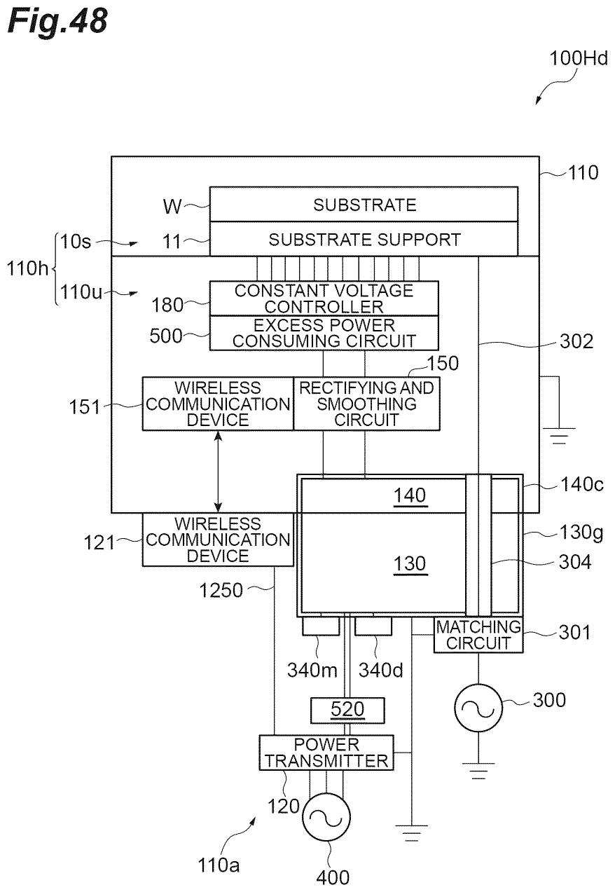

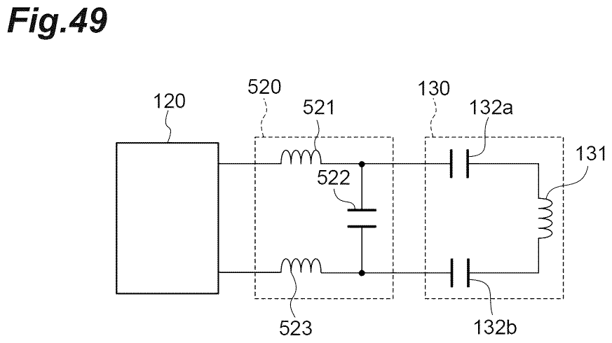

Reference is made to FIGS. 47 to 49. FIGS. 47 and 48 are diagrams schematically illustrating plasma processing apparatuses according to yet other example embodiments. FIG. 49 is a diagram illustrating an immittance converter in a plasma processing apparatus according to yet another example embodiment. Hereinafter, the plasma processing apparatus 100Hc illustrated in FIG. 47 will be described from the perspective of its differences from the plasma processing apparatus 100H illustrated in FIG. 36. Hereinafter, the plasma processing apparatus 100Hd illustrated in FIG. 48 will also be described from the perspective of its differences from the plasma processing apparatus 100Hb illustrated in FIG. 43.

Each of the plasma processing apparatuses 100Hc and 100Hd further includes an immittance converter 520. The immittance converter 520 includes an immittance conversion circuit connected between the power transmitter 120 and the transmitting coil module 130. As illustrated in FIG. 49, the immittance conversion circuit of the immittance converter 520 includes an inductor 521, a capacitor 522, and an inductor 523.

A pair of power supply lines of the immittance conversion circuit connecting the power transmitter 120 and the transmitting coil module 130 to each other may include the same components and have the same line length in order to suppress the phase difference and potential difference of conducted noise therebetween. For this reason, the power supply lines in the pair include the inductor 521 and the inductor 523, respectively. That is, the inductor 521 is connected between the power transmitter 120 and one end of the transmitting coil 131. The inductor 523 is connected between the power transmitter 120 and the other end of the transmitting coil 131. The resonance capacitor 132a may be connected between the inductor 521 and one end of the transmitting coil 131. The resonance capacitor 132b may also be connected between the inductor 523 and the other end of the transmitting coil 131. Each of the inductor 521 and the inductor 523 may be a coil composed of a winding using a Litz wire in order to suppress a decrease in power supply efficiency. Each of the inductor 521 and the inductor 523 may be selected so as to have a withstand voltage against the sum of the transmission voltage and the conducted noise, and to have an allowable current equal to or greater than the transmission current. The inductor 523 may be omitted. In this case, the other end of the transmitting coil 131 (or the resonance capacitor 132b) is connected to the power transmitter 120 without passing through the inductor 523.

The capacitor 522 is connected between a node on the power supply line connecting the inductor 521 and one end of the transmitting coil 131 (or the resonance capacitor 132a) to each other and a node on the power supply line connecting the inductor 523 and the other end of the transmitting coil 131 (or the resonance capacitor 132b) to each other. The capacitor 522 may be composed of one or more capacitors. The capacitor 522 may have a capacitance selected so as to form a resonance circuit together with the transmitting coil module 130. Each of the one or more capacitors forming the capacitor 522 may be a non-polarized film capacitor or a ceramic capacitor (for example, a multilayer ceramic capacitor). Each of the one or more capacitors forming the capacitor 522 may also be selected so as to have a withstand voltage against the sum of the transmission voltage and the conducted noise, and to have an allowable current equal to or greater than the transmission current.

Since the immittance converter 520 provides a constant current source together with the power transmitter 120, a constant current is supplied to the transmitting coil 131, and a constant voltage is supplied to the load. Therefore, with the immittance converter 520, it is possible to perform constant voltage control for the load while accommodating a wide range of load variations even in a configuration that does not include the energy storage 160.

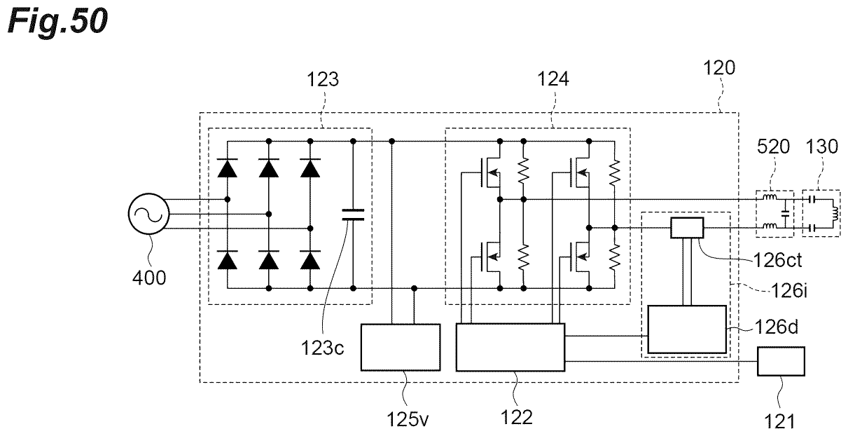

Hereinafter, reference is made to FIG. 50. FIG. 50 is a diagram illustrating a power transmitter that may be employed in plasma processing apparatuses according to various example embodiments. As illustrated in FIG. 50, the rectifying and smoothing circuit 123 of the power transmitter 120 has a rectifier circuit that is a diode bridge and a smoothing circuit including a smoothing capacitor 123c. The current detector 126i may also include a current transformer 126ct and a transmission current monitor 126d. The transmission current monitor 126d is configured to monitor the transmission current by monitoring the current output from the current transformer 126ct.

In one embodiment, the above-described smoothing capacitor 123c may have a large capacitance in order to reduce the ripple of the transmission voltage and reduce the ripple of the transmission power. For example, the smoothing capacitor 123c may have a capacitance of 0.1 mF or more, 0.5 mF or more, or 1 mF or more.

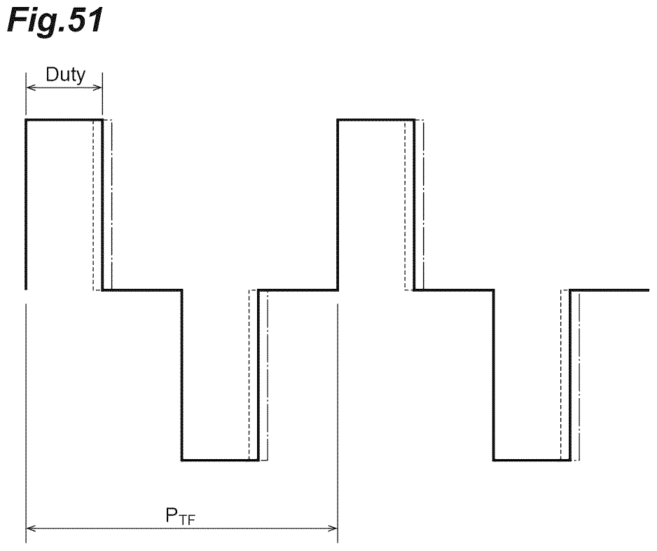

Hereinafter, reference is made to FIG. 51 together with FIG. 50. FIG. 51 is a diagram for explaining adjustment of a duty of a transmission voltage of a power transmitter that may be employed in plasma processing apparatuses according to various example embodiments. FIG. 51 illustrates waveforms of transmission voltages that can be transmitted from the power transmitter 120, shown by a solid line, a dashed line, and a dash-dot line. In FIG. 51, a period P_{TF} is a period of the transmission voltage having a time length that is the reciprocal of the transmission frequency, and Duty indicates the duty of the transmission voltage.

In one embodiment, the controller 122 of the power transmitter 120 may control the inverter 124 to adjust the duty of the transmission voltage so as to reduce the ripple of the transmission power output from the power transmitter 120 even if the output voltage of the rectifying and smoothing circuit 123 includes a ripple. Specifically, the controller 122 sets the duty of the transmission voltage at the peak of the ripple (see the dashed line in FIG. 51) to a value smaller than the duty of the transmission voltage in the case of the intermediate value of the ripple (see the solid line in FIG. 51), in accordance with the voltage detected by the voltage detector 125v. The controller 122 also sets the duty of the transmission voltage at the trough of the ripple (see the dash-dot line in FIG. 51) to a value larger than the duty of the transmission voltage in the case of the intermediate value of the ripple, in accordance with the voltage detected by the voltage detector 125v.

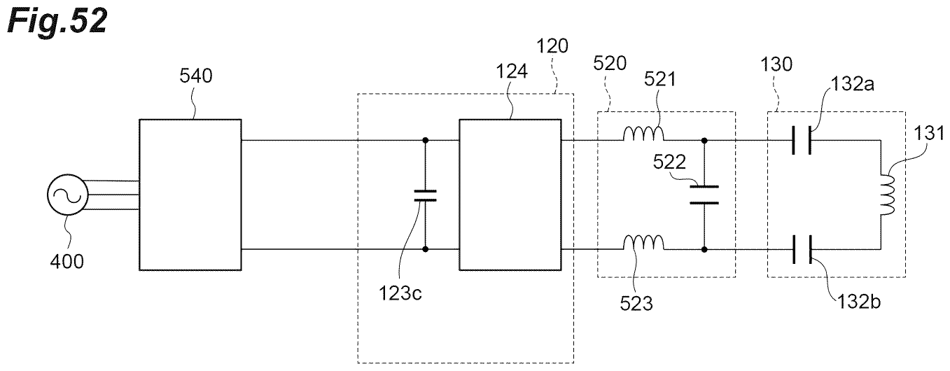

Hereinafter, reference is made to FIG. 52. FIG. 52 is a diagram illustrating a power transmitter and an AC/DC converter that may be employed in plasma processing apparatuses according to various example embodiments. In the embodiment illustrated in FIG. 52, the power transmitter 120 does not include the rectifying and smoothing circuit 123 but includes the smoothing capacitor 123c forming the above-described smoothing circuit. That is, the power transmitter 120 does not include the above-described rectifier circuit (for example, a diode bridge). In the embodiment illustrated in FIG. 52, an AC/DC converter 540 is connected between the AC power source 400 and the power transmitter 120. The AC/DC converter 540 may be a power supply or the like equipped with a PFC (Power Factor Correction) circuit. The PFC circuit can suppress a decrease in power supply efficiency. With the AC/DC converter 540, since the ripple of the output voltage and output power from the AC/DC converter 540 is reduced, the ripple of the transmission voltage output from the power transmitter 120 is reduced, and the ripple of the transmission power is reduced. In addition, since the power transmitter 120 does not include the smoothing circuit, the power transmitter 120 can be reduced in size.

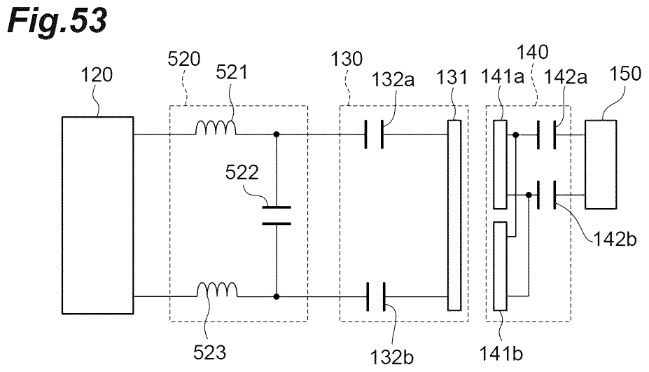

FIG. 53 is a diagram illustrating a receiving coil module 140 that may be employed in plasma processing apparatuses according to various example embodiments. In the example illustrated in FIG. 53, the receiving coil module 140 includes receiving coils 141a and 141b. One end of the receiving coil 141a and one end of the receiving coil 141b are connected to the rectifying and smoothing circuit 150 via the resonance capacitor 142a. The other end of the receiving coil 141a and the other end of the receiving coil 141b are connected to the rectifying and smoothing circuit 150 via the resonance capacitor 142b. As in the example illustrated in FIG. 53, in the receiving coil module 140, two or more receiving coils may be connected in parallel. This increases the allowable current of the receiving coils in the receiving coil module 140.

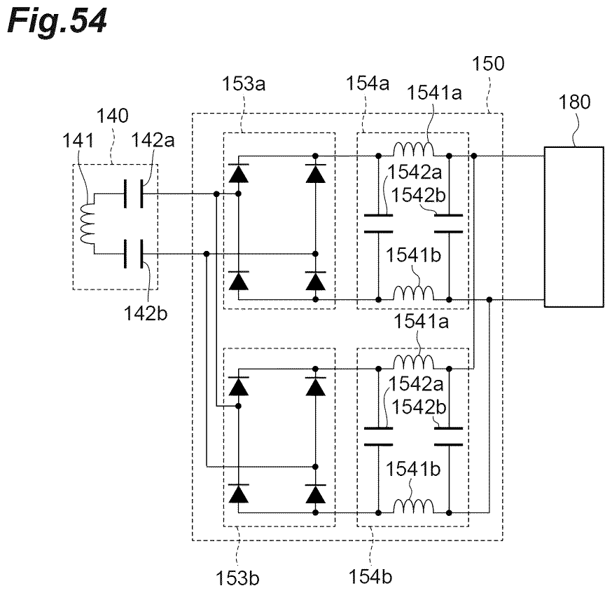

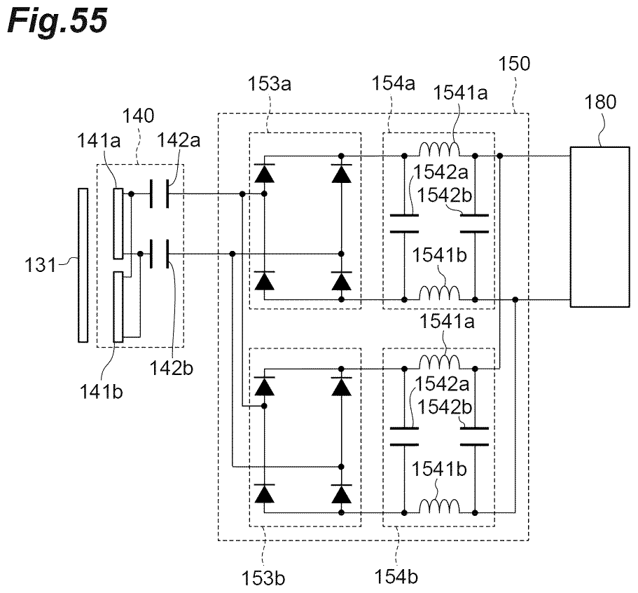

Hereinafter, reference is made to FIGS. 54 and 55. Each of FIGS. 54 and 55 is a diagram illustrating configurations of a receiving coil module and a rectifying and smoothing circuit that may be employed in plasma processing apparatuses according to various example embodiments. In the embodiment of FIG. 54, the receiving coil module 140 includes a single receiving coil 141. In the embodiment of FIG. 55, the receiving coil module 140 includes a plurality of receiving coils connected in parallel, for example, receiving coils 141a and 141b connected in parallel.

In each of the embodiments of FIGS. 54 and 55, the rectifying and smoothing circuit 150 includes a rectifier circuit 153a and a rectifier circuit 153b similar to the rectifier circuit 153, and a smoothing circuit 154a and a smoothing circuit 154b similar to the smoothing circuit 154. The rectifier circuit 153a is connected to the smoothing circuit 154a, and the rectifier circuit 153b is connected to the smoothing circuit 154b. In the rectifying and smoothing circuit 150 of each of the embodiments of FIGS. 54 and 55, the rectifier circuit 153b and the smoothing circuit 154b are parallelized with respect to the rectifier circuit 153a and the smoothing circuit 154a.

In the embodiment of FIG. 54, one end of the receiving coil 141 is connected to the rectifier circuit 153a and the rectifier circuit 153b via the resonance capacitor 142a. The other end of the receiving coil 141 is connected to the rectifier circuit 153a and the rectifier circuit 153b via the resonance capacitor 142b. In the embodiment of FIG. 55, one end of the receiving coil 141a and one end of the receiving coil 141b are connected to the rectifier circuit 153a and the rectifier circuit 153b via the resonance capacitor 142a. The other end of the receiving coil 141a and the other end of the receiving coil 141b are connected to the rectifier circuit 153a and the rectifier circuit 153b via the resonance capacitor 142b.

In each of the embodiments of FIGS. 54 and 55, each of the smoothing circuit 154a and the smoothing circuit 154b includes an inductor 1541a, an inductor 1541b, a capacitor 1542a, and a capacitor 1542b. The inductor 1541a is connected between one of a pair of inputs of the smoothing circuit (154a or 154b) and one of a pair of outputs of the smoothing circuit. The inductor 1541b is connected between the other of the pair of inputs of the smoothing circuit (154a or 154b) and the other of the pair of outputs of the smoothing circuit. By providing an inductor in each of the pair of power supply lines of each of the smoothing circuit 154a and the smoothing circuit 154b, the phase difference and potential difference of conducted noise between the pair of power supply lines are suppressed. The smoothing circuit 154 illustrated in FIG. 14 may also further include the inductor 1541b similarly to the smoothing circuit 154a and the smoothing circuit 154b.

In each of the embodiments of FIGS. 54 and 55, one end of the capacitor 1542a is connected to one of the pair of inputs of the smoothing circuit (154a or 154b) and one end of the inductor 1541a. The other end of the capacitor 1542a is connected to the other of the pair of inputs of the smoothing circuit (154a or 154b) and one end of the inductor 1541b. One end of the capacitor 1542b is connected to one of the pair of outputs of the smoothing circuit (154a or 154b) and the other end of the inductor 1541a. The other end of the capacitor 1542b is connected to the other of the pair of outputs of the smoothing circuit (154a or 154b) and the other end of the inductor 1541b.

According to each of the embodiments of FIGS. 54 and 55, the allowable current is increased by parallelizing units each including a rectifier circuit and a smoothing circuit. The inductance of the inductor 1541a and the inductance of the inductor 1541b may be equal to each other or may be different from each other. The capacitance of the capacitor 1542a of the smoothing circuit 154a, the capacitance of the capacitor 1542b of the smoothing circuit 154a, the capacitance of the capacitor 1542a of the smoothing circuit 154b, and the capacitance of the capacitor 1542b of the smoothing circuit 154b may be equal to each other or may be different from each other. Each of the smoothing circuit 154a and the smoothing circuit 154b need not have the inductor 1541b. Alternatively, the smoothing circuit 154a need not have the inductor 1541b, and the smoothing circuit 154b need not have the inductor 1541a.

### Integrated Configuration Related to Power Supply

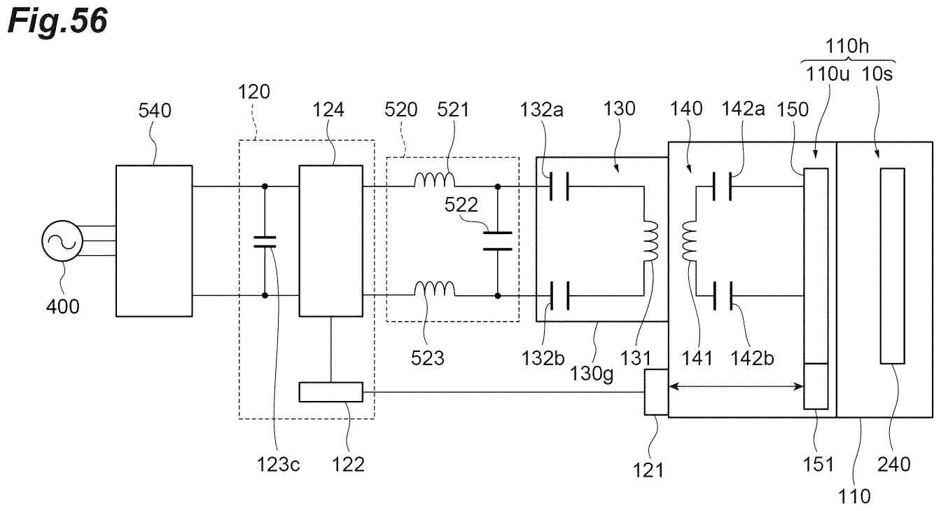

Hereinafter, reference is made to FIGS. 56 to 60. Each of FIGS. 56 to 60 is a diagram illustrating an integrated configuration related to power supply that may be employed in plasma processing apparatuses according to various example embodiments. The configuration of each of FIGS. 56 to 60 is employed in a plasma processing apparatus including the immittance converter 520 and the AC/DC converter 540.

In the embodiment illustrated in FIG. 56, the transmitting coil module 130 accommodates the transmitting coil 131, the resonance capacitor 132a, and the resonance capacitor 132b in the metal housing 130g.

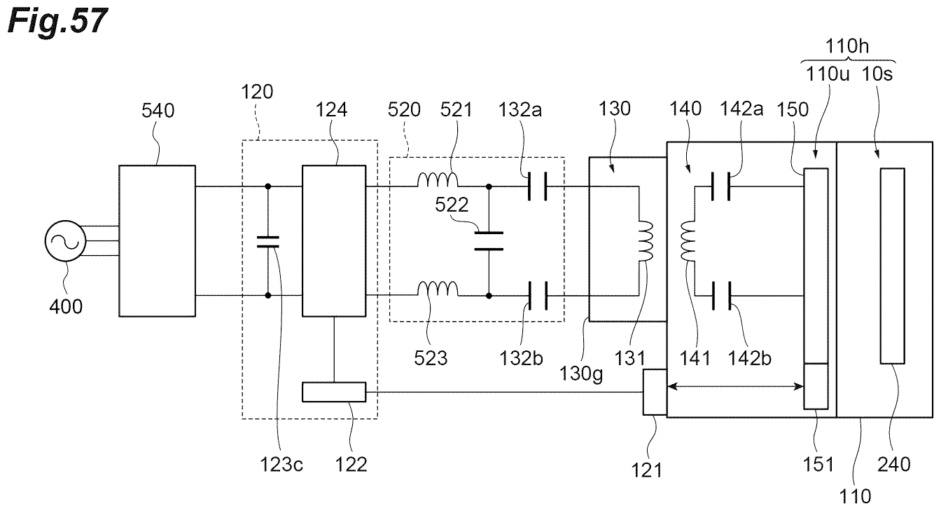

The embodiment illustrated in FIG. 57 differs from the embodiment illustrated in FIG. 56 in that the resonance capacitor 132a and the resonance capacitor 132b of the transmitting coil module 130 are integrated with the immittance converter 520. The resonance capacitor 132a and the resonance capacitor 132b may be disposed in a single housing together with the immittance conversion circuit of the immittance converter 520. According to the embodiment of FIG. 57, the transmitting coil module 130 can be reduced in size.

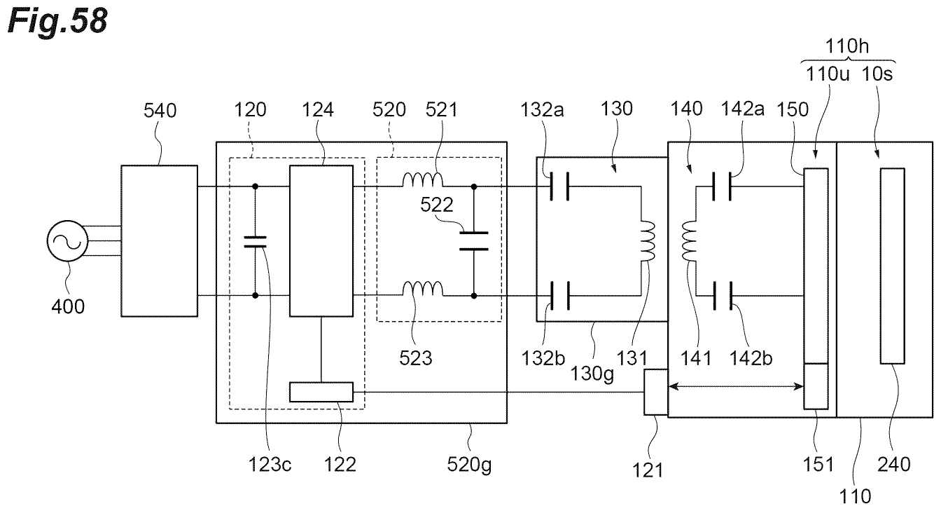

The embodiment illustrated in FIG. 58 differs from the embodiment illustrated in FIG. 56 in that the immittance converter 520 and the power transmitter 120 are integrated. The immittance converter 520 and the power transmitter 120 may be disposed in a single housing 520g. In this embodiment, the wiring between the inverter of the power transmitter 120 and the immittance converter 520 can be shortened. Therefore, power supply efficiency can be improved.

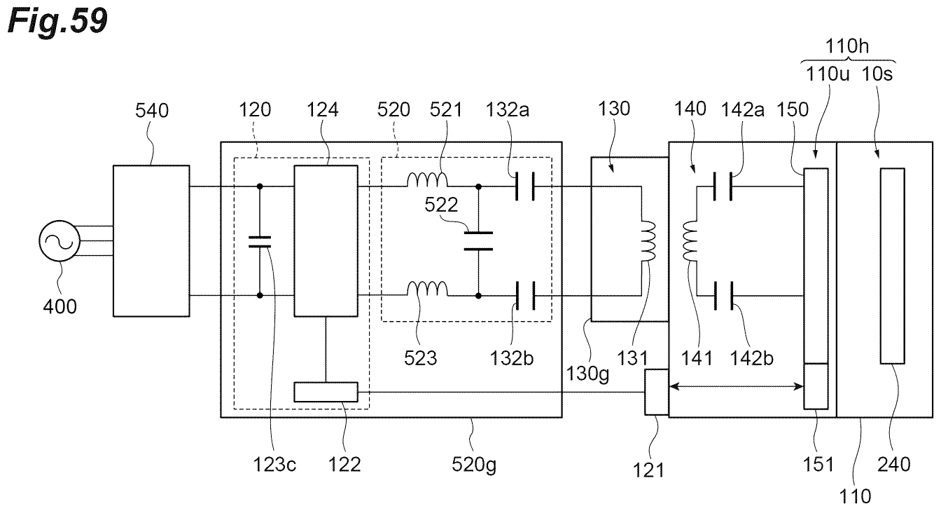

The embodiment illustrated in FIG. 59 differs from the embodiment illustrated in FIG. 56 in that the resonance capacitor 132a and the resonance capacitor 132b of the transmitting coil module 130, the immittance converter 520, and the power transmitter 120 are integrated. The resonance capacitor 132a and the resonance capacitor 132b of the transmitting coil module 130, the immittance converter 520, and the power transmitter 120 may be disposed in a single housing 520g. In this embodiment, the transmitting coil module 130 can be reduced in size. Further, in this embodiment, the wiring between the inverter of the power transmitter 120 and the immittance converter 520 can be shortened. Therefore, power supply efficiency can be improved.

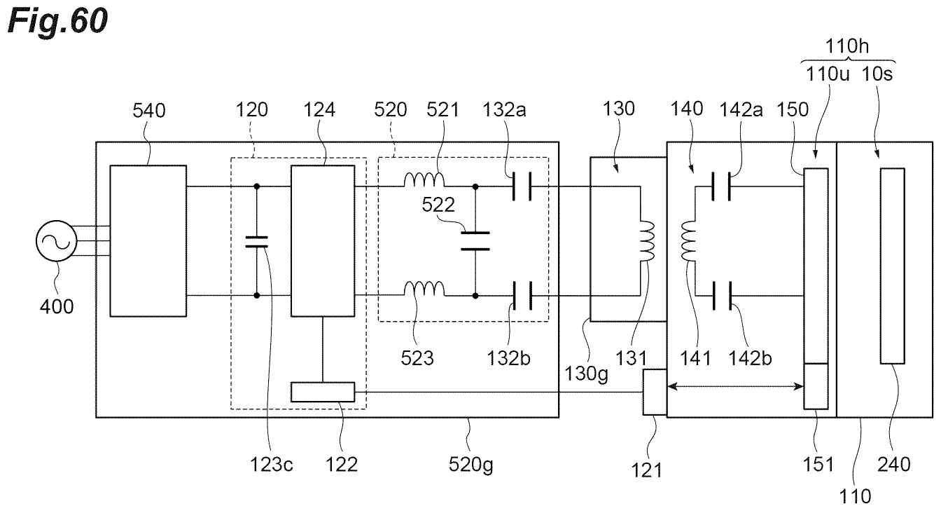

The embodiment illustrated in FIG. 60 differs from the embodiment illustrated in FIG. 56 in that the resonance capacitor 132a and the resonance capacitor 132b of the transmitting coil module 130, the immittance converter 520, the power transmitter 120, and the AC/DC converter 540 are integrated. The resonance capacitor 132a and the resonance capacitor 132b of the transmitting coil module 130, the immittance converter 520, the power transmitter 120, and the AC/DC converter 540 may be disposed in a single housing 520g. In this embodiment, the transmitting coil module 130 can be reduced in size. Further, in this embodiment, the wiring between the inverter of the power transmitter 120 and the immittance converter 520 can be shortened. Therefore, power supply efficiency can be improved. In addition, the degree of freedom in the layout between the AC power source 400 and the AC/DC converter 540 is increased.

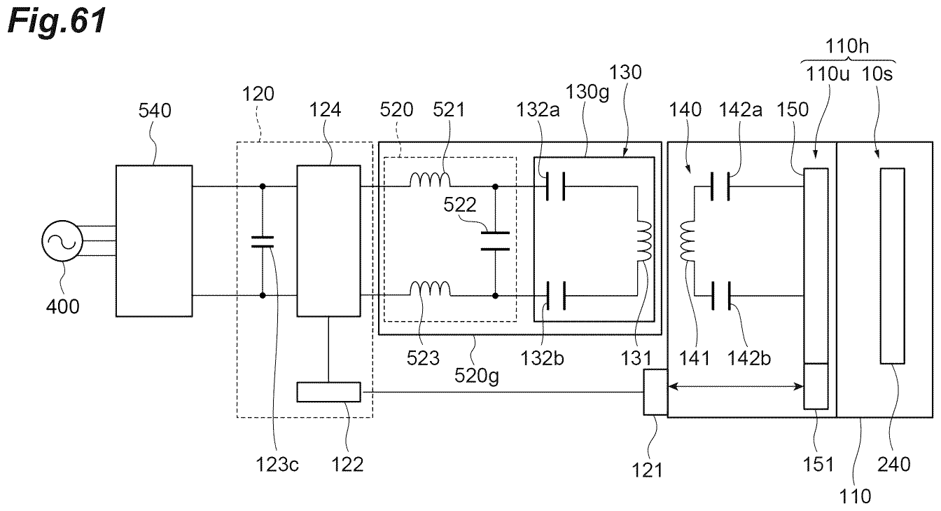

Hereinafter, reference is made to FIGS. 61 to 63. Each of FIGS. 61 to 63 is a diagram illustrating an integrated configuration related to power supply that may be employed in plasma processing apparatuses according to various example embodiments. The configuration of each of FIGS. 61 to 63 is employed in a plasma processing apparatus including the immittance converter 520 and the AC/DC converter 540.

In the embodiment illustrated in FIG. 61, the transmitting coil module 130 and the immittance converter 520 are integrated. The transmitting coil module 130 and the immittance converter 520 may be disposed in a single housing 520g (for example, a metal housing) or in the metal housing 130g. According to this embodiment, the wiring between the immittance converter 520 and the transmitting coil 131 can be shortened. Therefore, power supply efficiency can be improved.

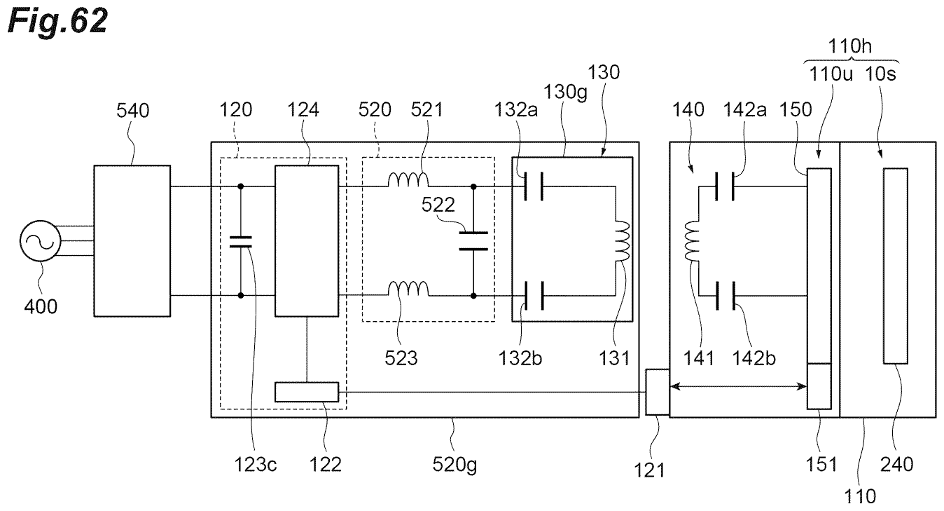

In the embodiment illustrated in FIG. 62, the transmitting coil module 130, the immittance converter 520, and the power transmitter 120 are integrated. The transmitting coil module 130, the immittance converter 520, and the power transmitter 120 may be disposed in a single housing 520g (for example, a metal housing) or in the metal housing 130g. According to this embodiment, the wiring between the inverter of the power transmitter 120 and the transmitting coil 131 can be shortened. Therefore, power supply efficiency can be improved.

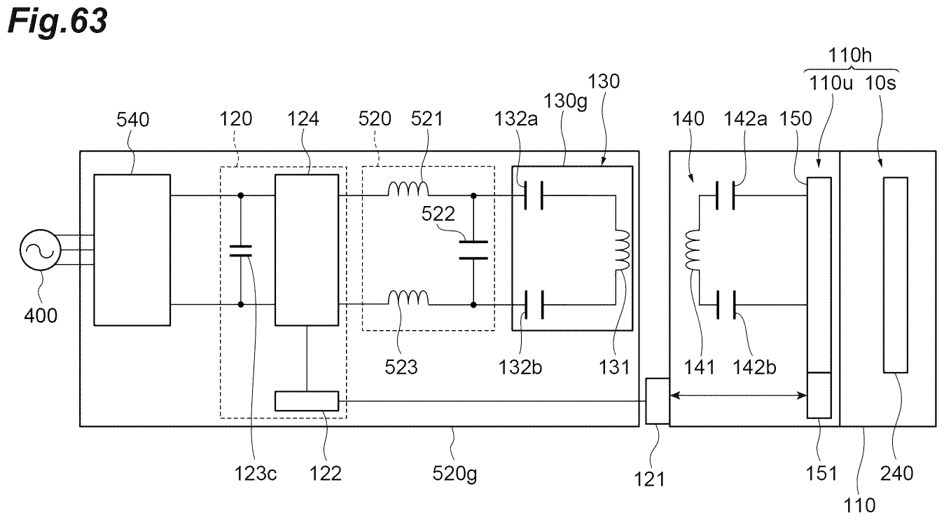

In the embodiment illustrated in FIG. 63, the transmitting coil module 130, the immittance converter 520, the power transmitter 120, and the AC/DC converter 540 are integrated. The transmitting coil module 130, the immittance converter 520, the power transmitter 120, and the AC/DC converter 540 may be disposed in a single housing 520g (for example, a metal housing) or in the metal housing 130g. According to this embodiment, the wiring between the AC/DC converter 540 and the transmitting coil 131 can be shortened. Therefore, power supply efficiency can be improved. In addition, the flexibility in the layout between the AC power source 400 and the AC/DC converter 540 is increased.

Although various example embodiments have been described above, various additions, omissions, substitutions, and changes may be made without being limited to the example embodiments described above. It is also possible to combine elements in different embodiments to form other embodiments.

Here, various example embodiments included in the present disclosure are described in [E1] to [E11] below.

[E1]

1. A plasma processing apparatus including:

a plasma processing chamber;

a substrate support in the plasma processing chamber;

a radio frequency power supply configured to generate radio frequency power;

an electrode or an antenna electrically connected to the radio frequency power supply and configured to receive the radio frequency power to generate plasma from a gas in the plasma processing chamber;

a load in the plasma processing chamber or in the substrate support;

a transmitting coil;

a receiving coil configured to receive power from the transmitting coil by electromagnetic induction coupling;

a rectifying and smoothing circuit configured to convert power from the receiving coil into DC power;

an energy storage electrically connected between the rectifying and smoothing circuit and the load; and

a ground frame that is configured to couple to ground and surrounds the substrate support together with the plasma processing chamber, the ground frame defining a space outside the plasma processing chamber to accommodate the rectifying and smoothing circuit and the energy storage in the space,

wherein

the transmitting coil is outside the ground frame, and

the receiving coil is in the space of the ground frame.

[E2]

The plasma processing apparatus according to E1, wherein the receiving coil is at a distance equal to or greater than an insulation distance from the ground frame.

[E3]

The plasma processing apparatus according to E1 or E2, wherein the receiving coil is directly connected to the rectifying and smoothing circuit.

[E4]

The plasma processing apparatus according to any one of E1 to E3, further including:

a power transmitter that supplies AC power to the transmitting coil; and

a radio frequency filter connected between the transmitting coil and the power transmitter and configured to cut radio frequency noise caused by the radio frequency power.

[E5]

The plasma processing apparatus according to any one of E1 to E4, further including a drive system configured to move the transmitting coil to change a distance between the receiving coil and the transmitting coil.

[E6]

The plasma processing apparatus according to any one of E1 to E5, further including:

at least one ferrite member extending on a back side of the receiving coil relative to the transmitting coil, surrounding an outer periphery of the receiving coil, extending on a back side of the transmitting coil relative to the receiving coil, and surrounding an outer periphery of the transmitting coil.

[E7]

The plasma processing apparatus according to E6, further including:

a metal housing that is configured to couple to ground, surrounds the transmitting coil outside the ground frame, and has an opening between the transmitting coil and the receiving coil,

wherein the transmitting coil is surrounded by the at least one ferrite member in a space surrounded by the metal housing.

[E8]

The plasma processing apparatus according to E7, further including:

an insulating housing including an insulating material, surrounding the receiving coil in the space of the ground frame, and having an opening between the transmitting coil and the receiving coil.

[E9]

The plasma processing apparatus according to E8, further including:

at least one insulating plate including an insulating material and closing the opening of the metal housing and the opening of the insulating housing.

[E10]

The plasma processing apparatus according to E9, further including:

a first cooler configured to cool the transmitting coil; and

a second cooler configured to cool the receiving coil. [E11]

The plasma processing apparatus according to E8, wherein

the metal housing and the insulating housing are connected to define a single space accommodating the transmitting coil and the receiving coil therein, and

the plasma processing apparatus further includes a cooling mechanism that is outside the ground frame and outside the metal housing and configured to cool the transmitting coil and the receiving coil.

[E12]

The plasma processing apparatus according to E2, wherein

the receiving coil is directly connected to the rectifying and smoothing circuit.

From the above description, it will be understood that various embodiments of the present disclosure have been described herein for purposes of illustration, and that various modifications may be made without departing from the scope and spirit of the present disclosure. Accordingly, the various embodiments disclosed herein are not intended to be limiting, and the true scope and spirit are indicated by the appended claims.

What is claimed is:

1. A plasma processing apparatus comprising:
a plasma processing chamber;
a substrate support in the plasma processing chamber;
a radio frequency power supply configured to generate radio frequency power;
an electrode or an antenna electrically connected to the radio frequency power supply and configured to receive the radio frequency power to generate plasma from a gas in the plasma processing chamber;
a load in the plasma processing chamber or in the substrate support;
a transmitting coil;
a receiving coil configured to receive power from the transmitting coil by electromagnetic induction coupling;
a rectifying and smoothing circuit configured to convert power from the receiving coil into DC power;
an energy storage electrically connected between the rectifying and smoothing circuit and the load; and
a ground frame that is configured to couple to ground and surrounds the substrate support together with the plasma processing chamber, the ground frame defining a space outside the plasma processing chamber to accommodate the rectifying and smoothing circuit and the energy storage in the space,
wherein
the transmitting coil is outside the ground frame, and
the receiving coil is in the space of the ground frame.

2. The plasma processing apparatus according to claim 1, wherein
the receiving coil is at a distance equal to or greater than an insulation distance from the ground frame.

3. The plasma processing apparatus according to claim 1, wherein
the receiving coil is directly connected to the rectifying and smoothing circuit.

4. The plasma processing apparatus according to claim 1, further comprising:
a power transmitter configured to supply AC power to the transmitting coil; and
a radio frequency filter connected between the transmitting coil and the power transmitter and configured to cut radio frequency noise caused by the radio frequency power.

5. The plasma processing apparatus according to claim 1, further comprising:
a drive system configured to move the transmitting coil to change a distance between the receiving coil and the transmitting coil.

6. The plasma processing apparatus according to claim 1, further comprising:
at least one ferrite member extending on a back side of the receiving coil relative to the transmitting coil, surrounding an outer periphery of the receiving coil, extending on a back side of the transmitting coil relative to the receiving coil, and surrounding an outer periphery of the transmitting coil.

7. The plasma processing apparatus according to claim 6, further comprising:
a metal housing that is configured to couple to ground, surrounds the transmitting coil outside the ground frame, and has an opening between the transmitting coil and the receiving coil,
wherein the transmitting coil is surrounded by the at least one ferrite member in a space surrounded by the metal housing.

8. The plasma processing apparatus according to claim 7, further comprising:
an insulating housing including an insulating material, surrounding the receiving coil in the space of the ground frame, and having an opening between the transmitting coil and the receiving coil.

9. The plasma processing apparatus according to claim 8, further comprising:
at least one insulating plate including an insulating material and closing the opening of the metal housing and the opening of the insulating housing.

10. The plasma processing apparatus according to claim 9, further comprising:
a first cooler configured to cool the transmitting coil; and
a second cooler configured to cool the receiving coil.

11. The plasma processing apparatus according to claim 8, wherein
the metal housing and the insulating housing are connected to define a single space accommodating the transmitting coil and the receiving coil therein, and
the plasma processing apparatus further comprises a cooling mechanism that is outside the ground frame and outside the metal housing and configured to cool the transmitting coil and the receiving coil.

12. The plasma processing apparatus according to claim 2, wherein
the receiving coil is directly connected to the rectifying and smoothing circuit.
